(19) United States
(12) Patent Application Publication
(10) Pub. No.: US 2025/0098232 A1
(43) Pub. Date: Mar. 20, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventor: Tzu-Ging LIN, Kaohsiung (TW)

(21) Appl. No.: 18/421,312

(22) Filed: Jan. 24, 2024

Related U.S. Application Data
(60) Provisional application No. 63/538,482, filed on Sep. 14, 2023.

(51) Int. Cl. H01L 29/06; H01L 27/02; H01L 29/423; H01L 29/66; H01L 29/775; H01L 29/78; H01L 29/786

(52) U.S. Cl. CPC H10D 62/102; H10D 30/024; H10D 30/62; H10D 30/6735; H10D 64/017; H10D 89/10; H10D 30/014; H10D 30/43; H10D 30/6757; H10D 62/121

(57) ABSTRACT

Embodiments of present disclosure relates to forming isolation structures in gate structures to prevent current leakage through source/drain regions (EPI), transistors, and silicon substrate. The isolation structures may be formed in the gate structure prior to or after the replacement gate sequence.

### CROSS-REFERENCE TO RELATED APPLICATIONS

This application claims priority to United States Provisional Patent Application Ser. No. 63/538,482, filed Sep. 14, 2023, which is incorporated by reference in its entirety.

### BACKGROUND

As the semiconductor industry has progressed into nanometer technology process nodes in pursuit of higher device density, higher performance, and lower costs, challenges from both fabrication and design issues have resulted in the development of multi-gate devices, such as fin field-effect transistors (FinFETs) and gate-all-around (GAA) transistors. To continue to provide the desired scaling and increased density for multi-gate devices in advanced technology nodes, continued reduction of the gate pitch is necessary.

Device layout may adopt polycrystalline silicon (poly) segments formed as diffusion edge (PODE) or continuous poly on diffusion edge (COPED) to avoid leakage between neighboring devices. A PODE pattern or a CPODE pattern is used to form the poly segments. As device dimension scales down, such as gate pitch, design schemes, such as PODE and CPODE schemes, may face difficulties to provide the level of device density, cell isolation, and device performance required for aggressively scaled circuits and devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1I schematically demonstrate a patterning design of isolation structures according to embodiments of the present disclosure.

FIGS. 2A-2R schematically demonstrate variation of the patterning designs of isolation structures according to embodiments of the present disclosure.

FIG. 3 is a flow chart of a method for manufacturing of a semiconductor substrate according to embodiments of the present disclosure.

FIGS. 4A-4C, 5A-5D, 6A-6C, 7A-7C, 8A-8C, 9A-9F, 10A-10D, 11A-11D, 12A-12E schematically illustrate various stages of manufacturing a semiconductor device according to embodiments of the present disclosure.

FIGS. 13A-13B and 14A-14C schematically illustrate various stages of manufacturing a semiconductor device according to embodiments of the present disclosure.

FIG. 15 is a flow chart of a method for manufacturing of a semiconductor substrate according to embodiments of the present disclosure.

FIGS. 16A-16C, 17A-17C, 18A-18C, 19A-19C, 20A-20F, 21A-21C, and 22A-22C schematically illustrate various stages of manufacturing a semiconductor device according to embodiments of the present disclosure.

FIGS. 23A-23B, 24A-24B, 25A-25B, and 26A-26B schematically illustrate various stages of manufacturing a semiconductor device according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain region refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process.

Embodiments of present disclosure relates to forming isolation structures in gate structures to prevent current leakage through source/drain regions (EPI), transistors, and silicon substrate. The isolation structures may be formed in the gate structure prior to or after the replacement gate sequence. Continuous polysilicon on diffusion edge (CPODE) processes, which involves silicon gate etch processes, may be performed prior to the replacement gate sequence. Continuous metal on diffusion edge (CMODE) processes, which involves metal gate etch processes, may be performed after the replacement gate sequence.

Embodiments of the present disclosure relate to method for used to patterning process for CPODE or CMODE to avoid photoresist peeling or pattern merge. A plurality of fin structures are first formed along a x-direction. Each fin structure may include one type of epitaxial semiconductor material for FinFET structure or multiple layers of epitaxial semiconductor layers of GAA structures. Multiple gate structures are then formed over the fin structures along a y-direction. The gate structures have a gate pitch along the x-direction. Source/drain regions are then formed along the fin structures and between the gate structures. A CPODE or CMODE opening pattern is first formed in a hard mask layer. The CPODE or CMODE pattern includes a group of isolation openings along a group of adjacent gate structures, i.e. along the y-direction. According to embodiments of the present disclosure, the CPODE or CMODE pattern includes isolation openings with non-uniform width along the x-direction. Particularly, the group of isolation openings includes at least one wide opening and one narrow openings. Each wide opening is positioned next to a narrow opening. The wide opening has a width along the x-direction is at least about 50% of the gate pitch. Multiple etching processes are then performed to remove exposed portions of the gate structures, the fin structures, and the substrate. An isolation material is then filled in place of the removed portions of the substrate, the fin structures, and the gate structures.

As the gate pitch decreases, the variation in width of the isolation openings avoids photoresist peeling, pattern merge and pattern loading in subsequent processes. The wide opening results in a greater etch depth into the substrate therefore ensures isolation between the source/drain regions and transistors.

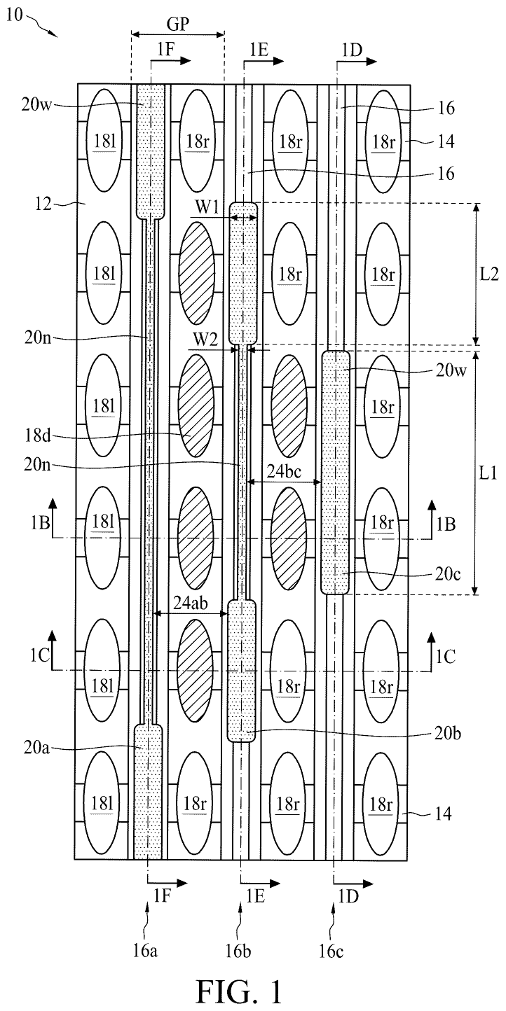

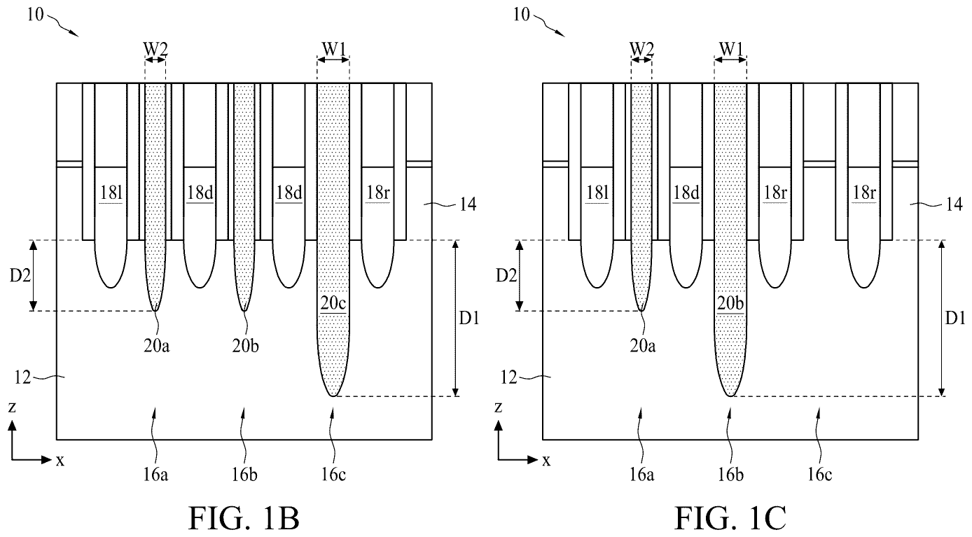

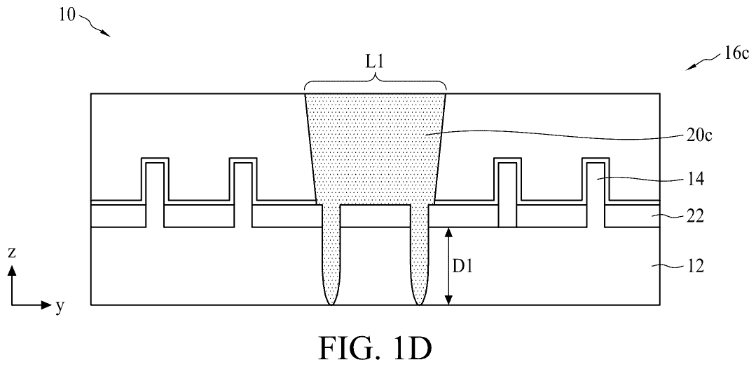

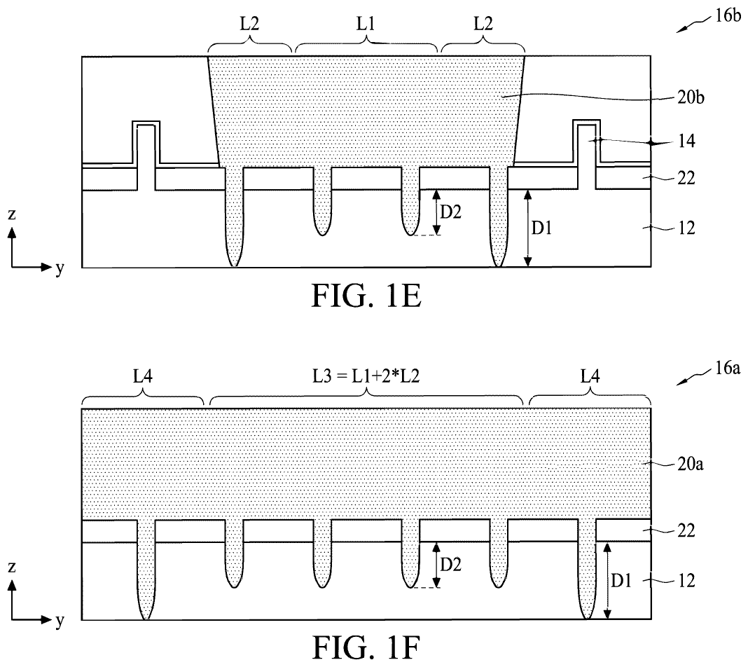

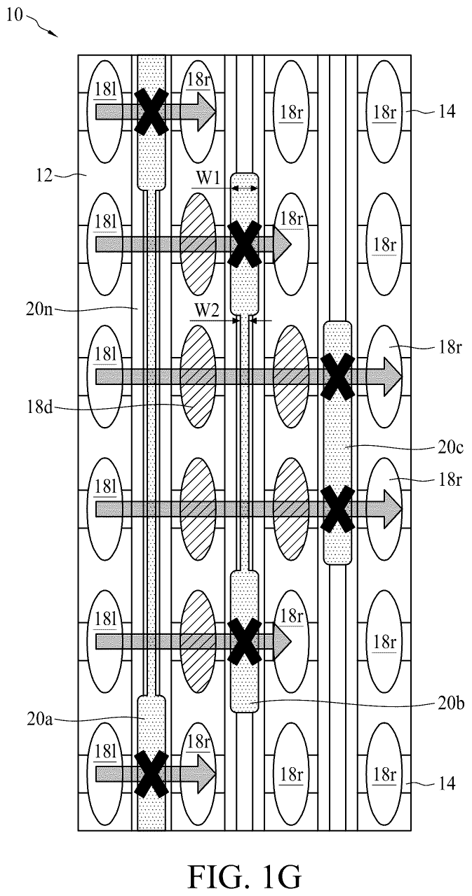

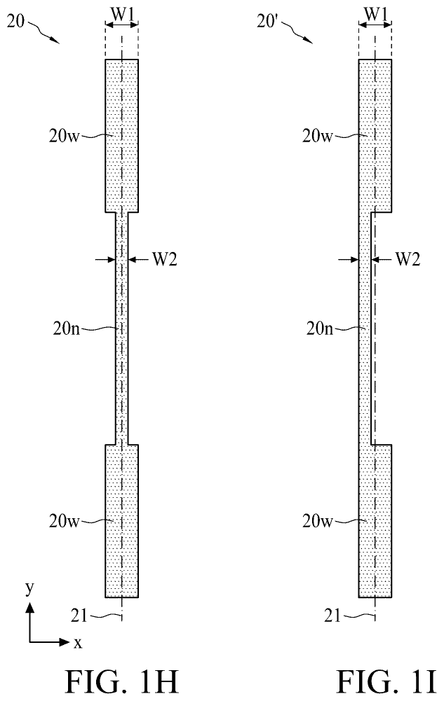

FIGS. 1A-1G schematically demonstrate a patterning design of isolation structures according to embodiments of the present disclosure. FIG. 1A is a schematic top view of a semiconductor device 10 according to the present disclosure. FIGS. 1B-1C are schematic cross-sectional views of the semiconductor device 10 along lines 1B-1B, 1C-1C of FIG. 1A, which are along fin structures in the semiconductor device 10. FIGS. 1D, 1E, and 1F are schematic cross-sectional views of the semiconductor device 10 along lines 1D-1D, 1E-1E, and 1F-1F in FIG. 1A, which are along gate structures in the semiconductor device 10. FIG. 1G is a schematic plan view of the semiconductor device 10 showing isolation structures preventing leak currents.

The semiconductor device 10 includes a plurality of transistors formed in and on a semiconductor substrate 12. Particularly, the semiconductor device 10 includes a plurality of fin structures 14 formed on the semiconductor substrate 12 along the x-direction. The fin structures 14 may include a single channel (for FinFET devices) or multiple channels (for GAA devices). A plurality of gate structures 16 (16a, 16b, 16c, collectively 16) formed over the fin structures 14 along the y-directions. Source/drain regions 18 are formed from the fin structures 14 between the gate structures 16. The gate structures 16 have a gate pitch GP. In some embodiments, the gate pitch GP is less than 50 nm, for example, the gate pitch is between about 20 nm and about 30 nm. The gate structures 20 may have a gate width GW along the x-direction. The source/drain regions 18 and the gate structures 16 in between form transistors. Isolation structures 20 are formed in portions of the gate structures 16 and extend into the semiconductor substrate 12 thereby electrically isolate the source/drain regions 18 on opposite sides of the isolation structures 20 (isolation structures 20a, 20b, 20c are shown, collectively isolation structure 20). The isolation structures 20 may be formed by a CPODE process or a CMODE process.

As shown in FIG. 1A, the isolation structures 20a, 20b, 20c are formed side-by-side in continuously adjacent gate structures 16a, 16b, 16c. As shown in FIGS. 1B-1E, the isolation structure 20a, 20b, 20c replaces a portion of the gate structures 16a, 16b, 16c, cuts up the fin structure 14 underneath, and extends into the semiconductor substrate 12. The isolation structures 20a, 20b, 20c cut up the fin structures 14 and electrically isolate the source/drain regions 181 to the left side from the isolation regions 18r to the right side. The source/drain regions 18 between the isolation structures 20 become dummy source/drain regions 18d.

During formation of the isolation structures 20 by a CPODE process or a CMODE process, a hard mask is first formed over the gate structures 16, followed by a photolithography process to form mask openings in the hard mask. It has been observed that a mask opening with a wider width along the x-direction results in a larger etch depth in the semiconductor substrate 12 while a mask opening with a narrower width along the x-direction results in a smaller etch depth in the semiconductor substrate 12.

As the gate pitch reduces, it becomes increasingly challenging to form mask openings side-by-side. For example, photoresist defects, such as peeling and scum, may occur. A gate pattern may include a 1D gate pitch and 2D gate pitch. The 1D gate pitch refers to the pitch along the direction of the fin structures, i.e., the x-direction. The 2D gate pitch refers to the pitch along the direction perpendicular to the fin structures, i.e., the y-direction. The gate pitch discussed hereafter refers to the 1D gate pitch. It also has been observed that the mask spacing along needs to be smaller than about 50% of the gate pitch to avoid peeling. When the gate pitch reduces, the mask spacing width may need to be greater than 50% of the gate pitch to achieve sufficient etch depth in the semiconductor substrate 12 to provide isolation. Embodiments of the present disclosure provide mask opening design that avoid photoresist defects without compromise isolation function.

In some embodiments, the isolation structures 20 are formed in two or more neighboring gate structures 16. In some embodiments, the isolation structures 20 formed in two or more neighboring gate structures 16 have staggered widths along the x-direction. For example, a wide isolation structure 20 is positioned parallel to one or two narrow isolation structures 20. In other words, two wide isolation structures 20 are not positioned next two each other. By arranging narrow isolation structures 20 next to the wide isolation structure 20, the isolation structure 20 may be formed without causing photoresist defects.

In some embodiments, the isolation structure 20 within one gate structure 16 may include a single segment with one width in the x-direction, such as the isolation structure 20c. Alternatively, the isolation structure 20 in one gate structure 16 may include two or more segments with different widths, such as the isolation structures 20a, 20b. Segments of the isolation structures 20 have different widths.

For example, the isolation structures 20 may include wide segments 20w with a width W1 along the x-direction and narrow sections with a width W2. The width W1 is greater than about 50% of the gate pitch GP. For example, the width W1 is in a range between about 0.5 GP and about 0.6 GP. The width W2 is in a range between about 0.25 GP and 0.5 GP. In some embodiments, the width W1 and the width W2 are selected so that the average widths of the isolation structures 20 is less than 0.5 GP, for example, the average width of the isolation structures 20 is between about 0.4 GP and 0.45 GP.

In some embodiments, adjacent segments of the isolation structures 20 in neighboring gate structures 16 may have different widths. For example, along the same fin structure 14, a wide segment 20w of the isolation structures 20 is positioned immediately next to one or two narrow segments 20n. The wide segment 20w of the isolation structure 20 has sufficient depth to provide isolation across the fin structure 14 while the adjacent narrow segments 20n of the isolation structure 20 to avoid photoresist defects during fabrication.

In some embodiments, a single isolation structure 20, such as the isolation structures 20a, 20b, may include wide segments 20w and narrow segments 20n. By connecting wide segments 20w and narrow segments 20n, length along the y-direction of the isolation structure 20 increases facilitating greater etch depth during fabrication.

FIG. 1H is a schematic top view of an isolation structure 20 with one narrow segment 20n connected to two wide segments 20w according to the present disclosure. The isolation structure 20 is symmetrical about a central axis 21. FIG. 1I is a schematic view of an isolation structure 20′ according to another embodiment. The isolation structure 20′ is similar to the isolation structure 20 except that the narrow segment 20n is disposed off center so that the isolation structure 20′ has a straight line along the y-direction on one side.

In some embodiments, the isolation structures 20 in the neighboring gate structure 16 also vary in lengths along the y-direction. For example, as shown in FIG. 1A, the neighboring isolation structures 20a, 20b, 20c have decreasing lengths. By decreasing the lengths of the isolation structures 20a, 20b, 20c, the number of dummy source/drain regions 18d also reduces, thus, increasing effective device density.

In the design of FIG. 1A, the isolation structure 20c includes one wide segment 20w having a length L1 and the width W1. The length L1 of the isolation structure 20c may be in a range between about 2 times of W1 and 10 times of W1. The length L1 may be chosen according to the circuit design. In some embodiments, the length L1 may be selected to ensure that the isolation structure reaches sufficient depth in the semiconductor substrate 12. The isolation structure 20c may extend across one or more fin structures 14. The isolation structure 20c may extend across one or more fin structures 14. As shown in FIG. 1D, the fin structures 14 are formed over the semiconductor substrate 12. A lower portion of the fin structures 14 are surrounded by a shallow trench isolation (STI) layer 22. The isolation structure 20c cuts up the two fin structures 14 underneath and extends into the semiconductor substrate 14. In some embodiments, the isolation structure 20c extends into the semiconductor substrate 14 for a depth D1 along the z-direction. The depth D1 is selected to ensure that the isolation structure 20c electrically isolate the source/drain region 181 from the source/drain region 18r, as shown in FIG. 1B. In some embodiments, the depth D1 is in a range between about 20 nm and about 90 nm.

The isolation structure 20b is immediately adjacent the insolation structure 20c. The isolation structure 20b includes two wide segments 20w connected by a narrow segment 20n. The narrow segment 20n has a length L1 or a length substantially equal to the isolation structure 20c, therefore, providing a spacing 24bc that is wider than about 50% of the gate pitch GP. The wide segments 20w are formed from two ends of the narrow segment 20n. For example, the isolation structure 20b may be similar to the isolation structure 20, 20′ in FIGS. 1H and 1I. Alternatively, the isolation structure 20b may include only one wide segment 20w and one narrow segment 20n. The wide segments 20w may have a length L2. The length L2 may be long enough to cover one or more fin structures 14. The isolation structure 20b has a total length L3, which equals L1 plus two times of L2. As shown in FIG. 1E, the isolation structure 20b cuts up the four fin structures 14 underneath and extends into the semiconductor substrate 14. In some embodiments, the narrow segment 20n of the isolation structure 20b extends into the semiconductor substrate 14 for a depth D2 along the z-direction while the wide segments 20w of the isolation structures 20b extend into the semiconductor substrate for a depth D1. The depth D2 less than the depth D1. In some embodiments, the depth D2 is in a range between about 0 nm and about 70 nm. In some embodiments, the difference between D1 and D2 is less than about 60 nm. In some embodiments, a ratio of D1:D2 is in a range between about 1.2 and about 3.0, for example between about 1.5 and about 2.0. In some embodiments, at the depth D2, the isolation structure 20b may not be sufficient to isolate the source/drain regions 18 on opposing sides of the isolation structure 20b. Thus, the wide segments 20w of the isolation structure 20b provide electric isolation across the fin structures 14 underneath. The narrow segment 20n of the isolation structure 20b does not provide electric isolation across the fin structures 14 underneath. The fin structures 14 under the narrow segment 20n of the isolation structure 20b rely on the isolation structure 20c for electrical isolation.

The isolation structure 20a is immediately adjacent the insolation structure 20b. Similar to the isolation structure 20b, the isolation structure 20a includes two wide segments 20w connected by a narrow segment 20n. The narrow segment 20n has a length L3 or a length substantially equal to the isolation structure 20b, therefore, providing a spacing 24ab that is wider than about 50% of the gate pitch GP. The wide segments 20w are formed from two ends of the narrow segment 20n. The wide segments 20w may have a length L4. The length L4 may be long enough to cover one or more fin structures 14. As shown in FIG. 1F, the isolation structure 20c cuts up the six fin structures 14 underneath and extends into the semiconductor substrate 14. In some embodiments, the narrow segment 20n of the isolation structure 20a extends into the semiconductor substrate 14 for a depth D2 along the z-direction while the wide segments 20w of the isolation structures 20a extend into the semiconductor substrate for a depth D1. Thus, the wide segments 20w of the isolation structure 20a provide electric isolation across the fin structures 14 underneath. The narrow segment 20n of the isolation structure 20a does not provide electric isolation across the fin structures 14 underneath. The fin structures 14 under the narrow segment 20n of the isolation structure 20a rely on the isolation structures 20c and 20b for electrical isolation.

FIG. 1G schematically illustrates current isolation across the fin structures 14. X marks in FIG. 1G indicates electric isolations across two sides of the fin structures 14. As shown in FIG. 1G, the wide segments 20w of the isolation structures 20a, 20b, 20c provide electric isolation across the fin structures 14. Even though each fin structure 14 may be cut into segments by one or more isolation structures 20. However not every isolation structure 20 that intersects with a fin structure 14 functions to provide electrical isolation to the fin structure 14.

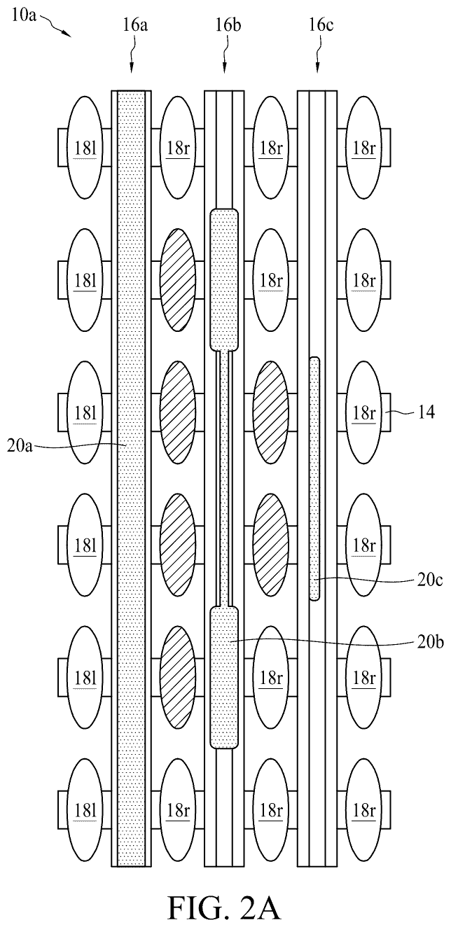

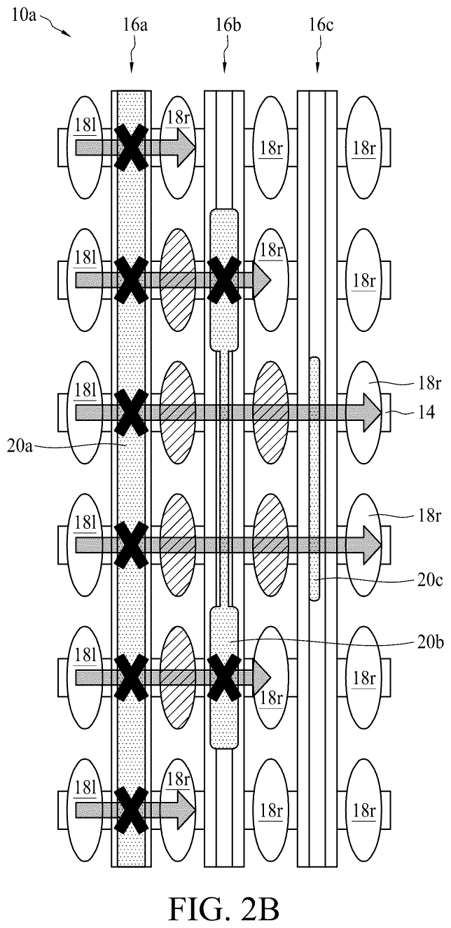

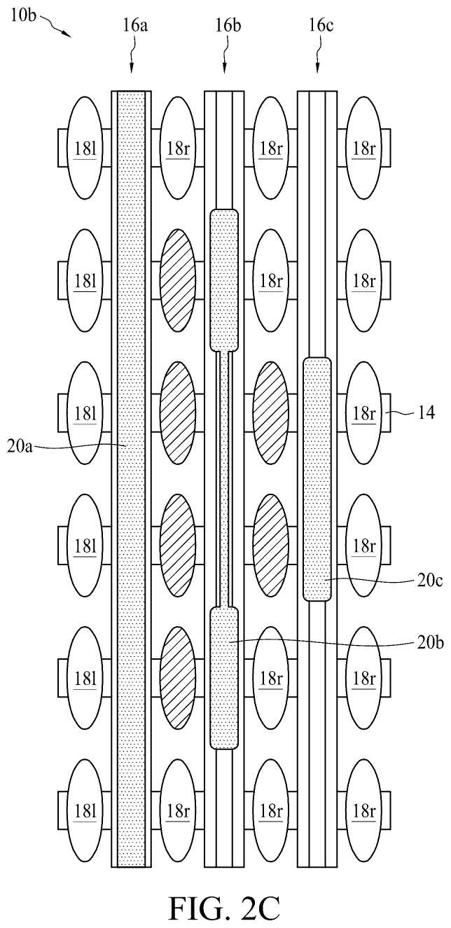

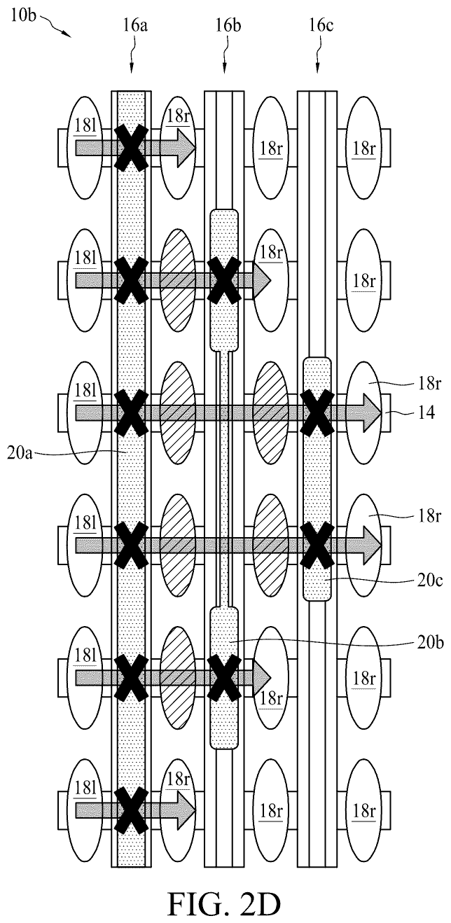

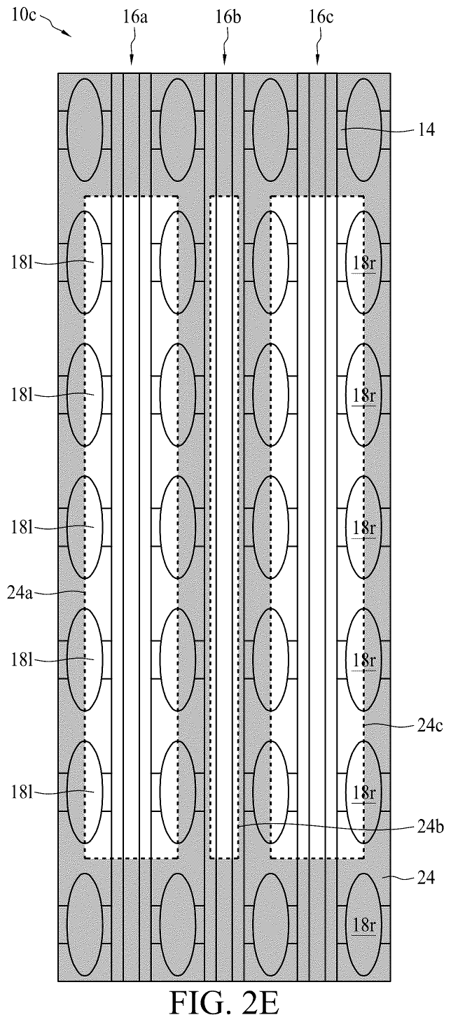

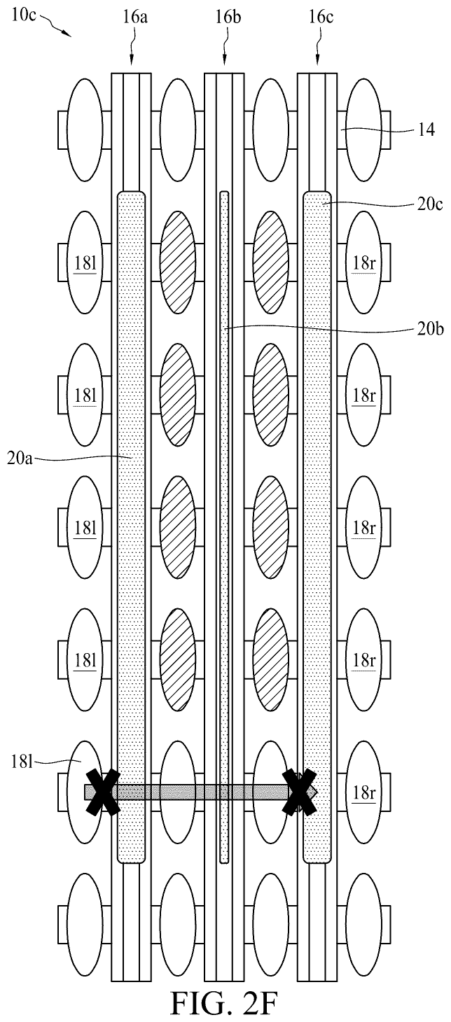

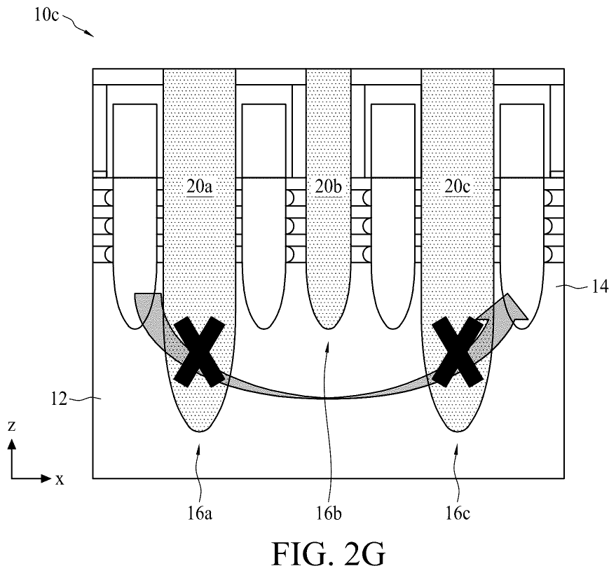

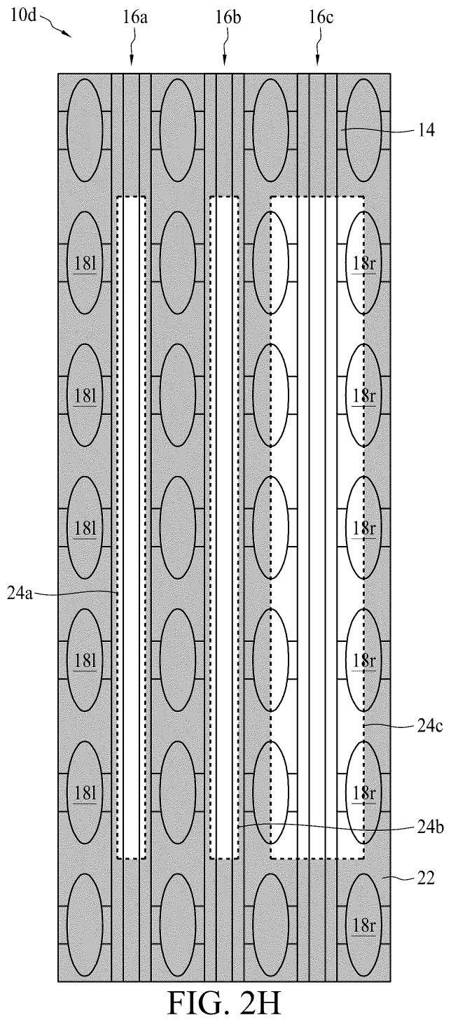

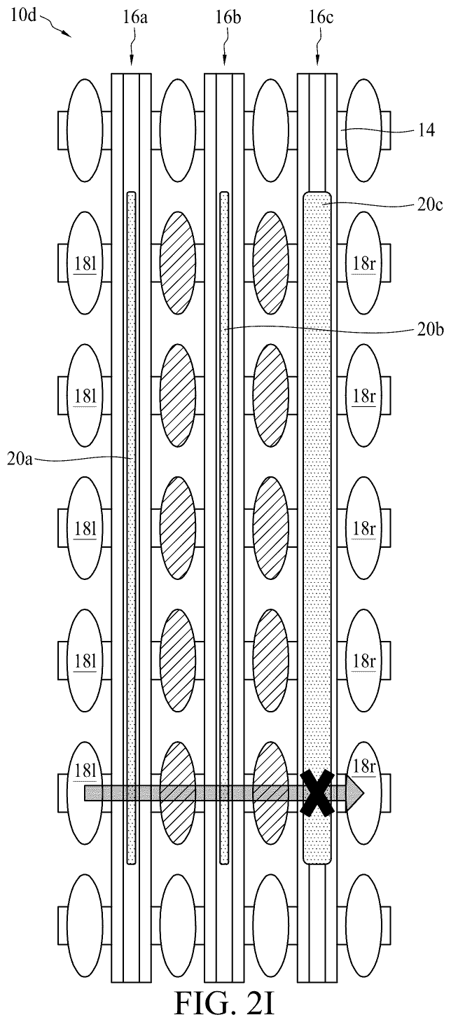

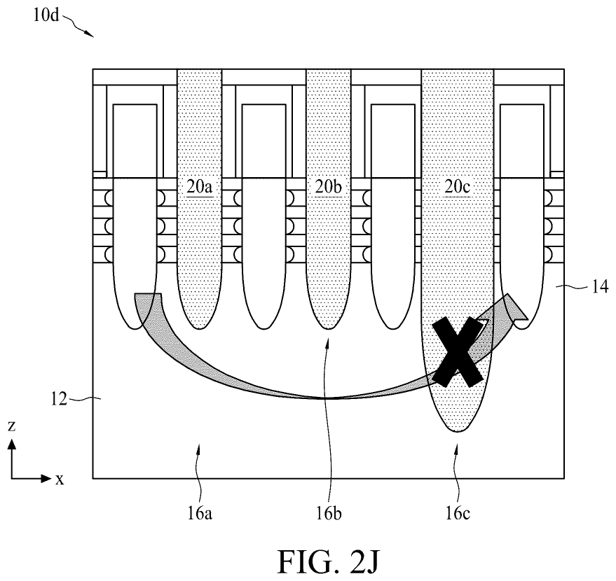

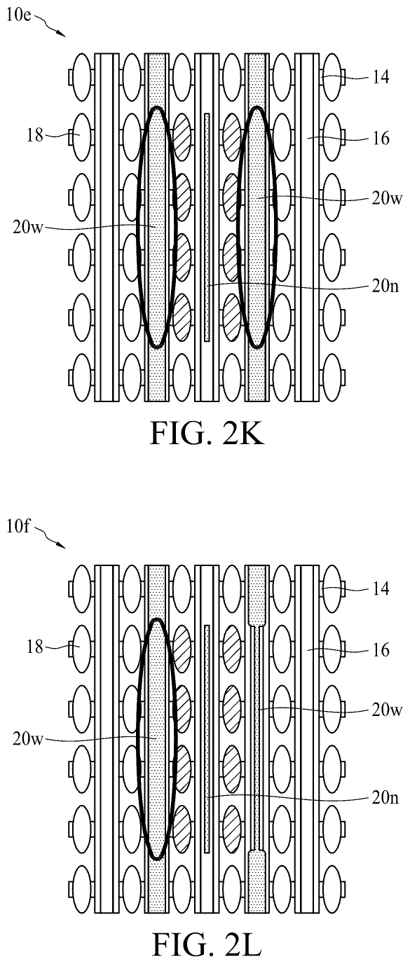

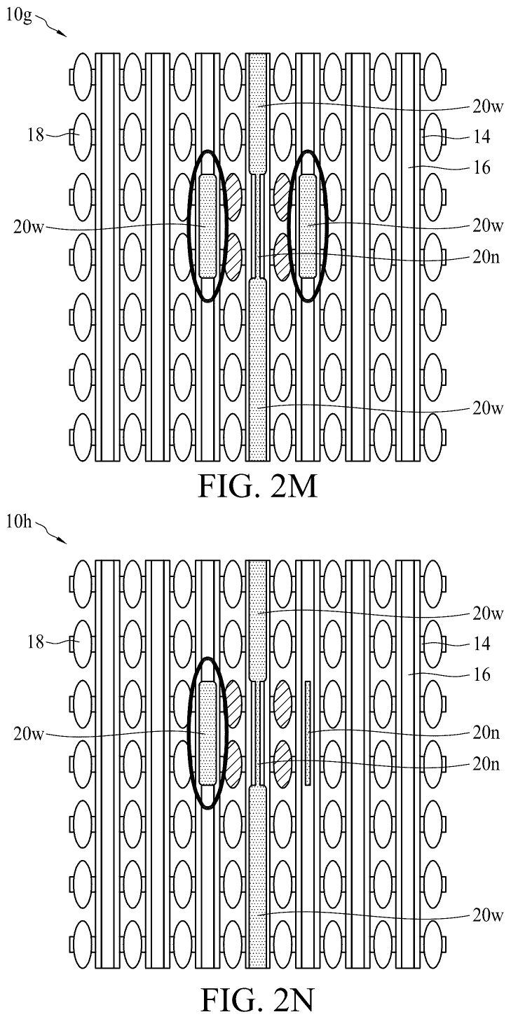

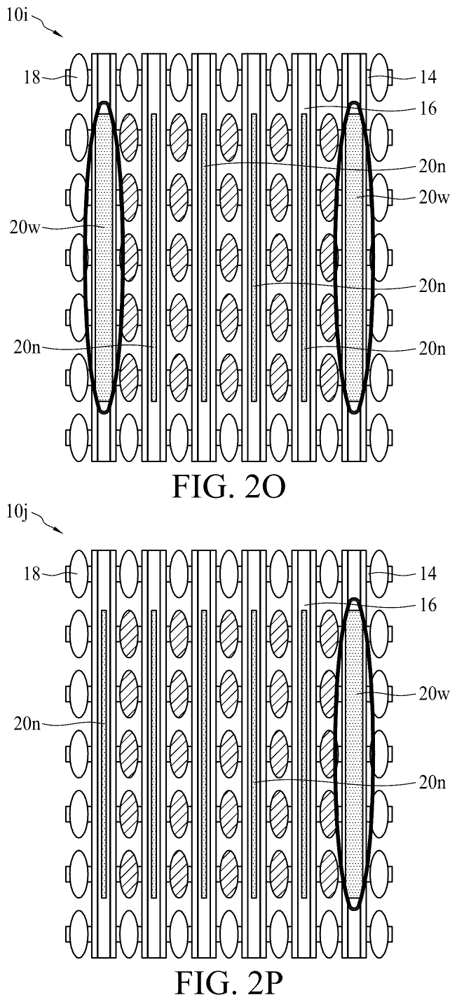

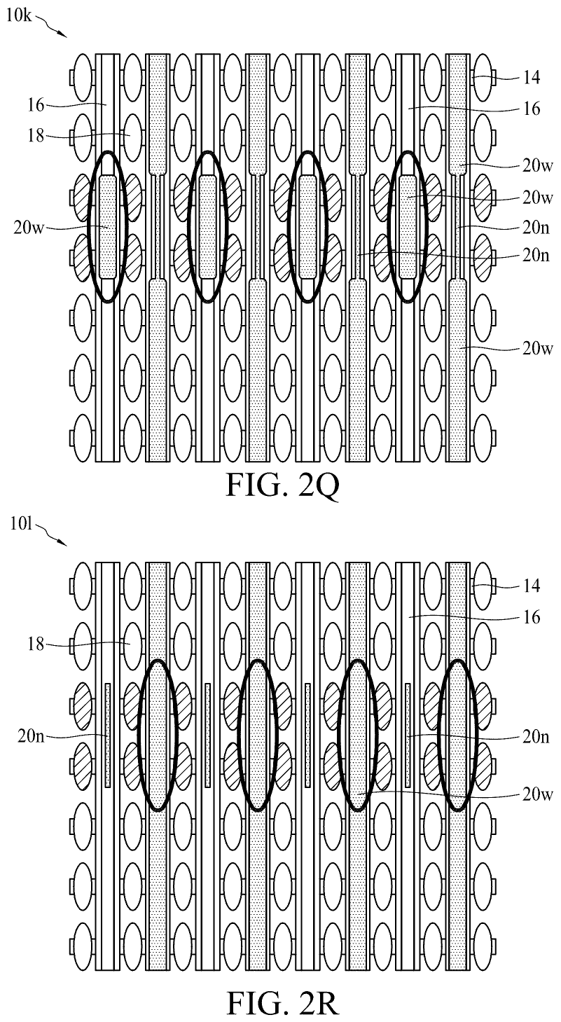

As discussed above, embodiments of the present disclosure arrange narrow segments and wide segments of isolation structures to achieve effective isolation and avoid photoresist defects at the same time. The wide and narrow segments may be arranged in various designs. FIGS. 2A-2Q schematically demonstrate variation of the patterning designs of isolation structures according to embodiments of the present disclosure.

FIGS. 2A-2B are schematic top views of a semiconductor device 10a according to embodiments of the present disclosure. The semiconductor device 10a is similar to the semiconductor device 10 with a different arrangement of narrow and wide segments in isolation structures. In the semiconductor device 10a, the isolation structure 20a on the left side includes a singular wide segment 20w, the isolation structure 20c on the right side includes a singular narrow segment 20n, and the isolation structure 20b in the middle includes a narrow segment 20n connected two wide segment 20w. As shown in FIG. 2B, the isolation structure 20a on the left side provides electrical isolation to the source/drain regions 181 in the fin structures 14 from the remainder of the source/drain regions 18, and wide segments of the isolation structure 20b provide additional electrical isolation to the source/drain regions 18r in the fin structures 14.

FIGS. 2C-2D are schematic top views of a semiconductor device 10b according to embodiments of the present disclosure. The semiconductor device 10b is similar to the semiconductor device 10a with a different arrangement of narrow and wide segments in isolation structures. In the semiconductor device 10b, the isolation structure 20a on the left side includes a singular wide segment 20w, the isolation structure 20c on the right side includes a wide segment 20w, and the isolation structure 20b in the middle includes a narrow segment 20n connected two wide segment 20w. As shown in FIG. 2D, the isolation structure 20a on the left right provides electrical isolation to the source/drain regions 181 in the fin structures 14 from the remainder of the source/drain regions 18, and the isolation structure 20c on the right side and wide segments of the isolation structure 20b provide additional electrical isolation to the source/drain regions 18r in the fin structures 14 from the remainder of the source/drain regions 18.

FIGS. 2E, 2F, and 2G schematically illustrate a semiconductor device 10c according to embodiments of the present disclosure. FIGS. 2E-2F are schematic top views of the semiconductor device 10c according to embodiments of the present disclosure. FIG. 2G is a schematic sectional view of the semiconductor device 10c along the fin structure 14. The semiconductor device 10c is similar to the semiconductor device 10 with a different arrangement of narrow and wide segments in isolation structures. In the semiconductor device 10c, each of the isolation structures 20a, 20b, 20c includes a singular segment. The wide and narrow segments are alternatively arranged over the gate structures 16. FIG. 2E schematically illustrates the semiconductor device 10c at the stage while mask openings 24a, 24b, 24c are formed through a mask layer 24. As shown in FIG. 2F, each of the isolation structure 20a on the left side and the isolation structure 20c on the right side includes a singular wide segment 20w, and the isolation structure 20b in the middle includes a singular narrow segment 20n. As shown in FIGS. 2F and 2G, the isolation structure 20a on the left right and the isolation structure 20c on the right side provide electrical isolation between the source/drain regions 181 and the source/drain regions 18r in the fin structures 14.

FIGS. 2H, 2I, and 2J schematically illustrate a semiconductor device 10d according to embodiments of the present disclosure. FIGS. 2H-2I are schematic top views of the semiconductor device 10d according to embodiments of the present disclosure. FIG. 2J is a schematic sectional view of the semiconductor device 10d along the fin structure 14. The semiconductor device 10d is similar to the semiconductor device 10c with a different arrangement of narrow and wide segments in isolation structures. In the semiconductor device 10d, each of the isolation structures 20a, 20b, 20c includes a singular segment. The isolation structure 20c on the right side includes a singular wide segment 20w, and each of the isolation structure 20b in the middle and the isolation structure 20a on the left includes a singular narrow segment 20n. As shown in FIGS. 2I and 2J, the isolation structure 20c on the right side provides electrical isolation between the source/drain regions 181 and the source/drain regions 18r in the fin structures 14.

FIG. 2K is a schematic top view of a semiconductor device 10e according to embodiments of the present disclosure. The semiconductor device 10e includes a design of the isolation structure. The semiconductor device 10e includes isolation structures 20 over a group of gate structures 16. The semiconductor device 10e includes two wide isolation structures 20w formed over outside gate structures 16 with narrow isolation structure 20n formed over interior gate structures 16 of the group of the gate structure 16. In some embodiments, the wide isolation structures 20w are long segments and the narrow isolation structures 20n are short segments. In some embodiments, a plurality of short narrow segments 20n may be formed over each interior gate structure 16.

FIG. 2L is a schematic top view of a semiconductor device 10f according to embodiments of the present disclosure. The semiconductor device 10f includes a design of the isolation structure. The semiconductor device 10f includes isolation structures 20 over a group of gate structures 16. The semiconductor device 10e includes one wide isolation structure 20w formed over one side over the group of the gate structures 16 with narrow isolation structures 20n formed over the remainder of the group of the gate structure 16. In some embodiments, the wide isolation structures 20w are long segments and the narrow isolation structures 20n are short segments. Alternatively, one or more narrow isolation structures 20n may be arranged with wide segments.

FIG. 2M is a schematic top view of a semiconductor device 10g according to embodiments of the present disclosure. The semiconductor device 10g includes a design of the isolation structure. The semiconductor device 10g includes two wide isolation structures 20w formed over outside gate structures 16 and a narrow isolation structure 20n formed between the two wide isolation structures 20w. In some embodiments, the middle narrow isolation structure 20n may be connected to wide isolation structures 20w.

FIG. 2N is a schematic top view of a semiconductor device 10h according to embodiments of the present disclosure. The semiconductor device 10h includes a design of the isolation structure. The semiconductor device 10h is similar to the semiconductor device 10g in FIG. 2M that the semiconductor device 10h includes one wide isolation structure 20w and one narrow isolation structure 20n formed over outside gate structures 16.

FIG. 2O is a schematic top view of a semiconductor device 10i according to embodiments of the present disclosure. The semiconductor device 10i includes a design of the isolation structure. The semiconductor device 10i includes isolation structures 20 over a group of gate structures 16. The semiconductor device 10i is similar to the semiconductor device 10e except that the isolation structures 20 in the semiconductor device 10i are short segments. The semiconductor device 10i includes two wide isolation segments 20w formed over outside gate structures 16 with narrow isolation segments 20n formed over interior gate structures 16 of the group of the gate structure 16.

FIG. 2P is a schematic top view of a semiconductor device 10j according to embodiments of the present disclosure. The semiconductor device 10j includes a design of the isolation structure. The semiconductor device 10j includes isolation structures 20 over a group of gate structures 16. The semiconductor device 10j is similar to the semiconductor device 10i of FIG. 2O except that the semiconductor device 10j includes only one wide isolation structures 20w on the outside gate structures 16.

FIG. 2Q is a schematic top view of a semiconductor device 10k according to embodiments of the present disclosure. The semiconductor device 10k includes a design of the isolation structure. The semiconductor device 10k is similar to the semiconductor device 10g in FIG. 2M except that the semiconductor device 10k includes alternatively arranged short wide isolation structures 20w and long isolation structures with short segments 20n.

FIG. 2R is a schematic top view of a semiconductor device 10l according to embodiments of the present disclosure. The semiconductor device 10l includes a design of the isolation structure. The semiconductor device 10l, is similar to the semiconductor device 10k in FIG. 2Q that the semiconductor device 10l includes alternatively arranged short narrow isolation structures 20n and long wide isolation structures 20w.

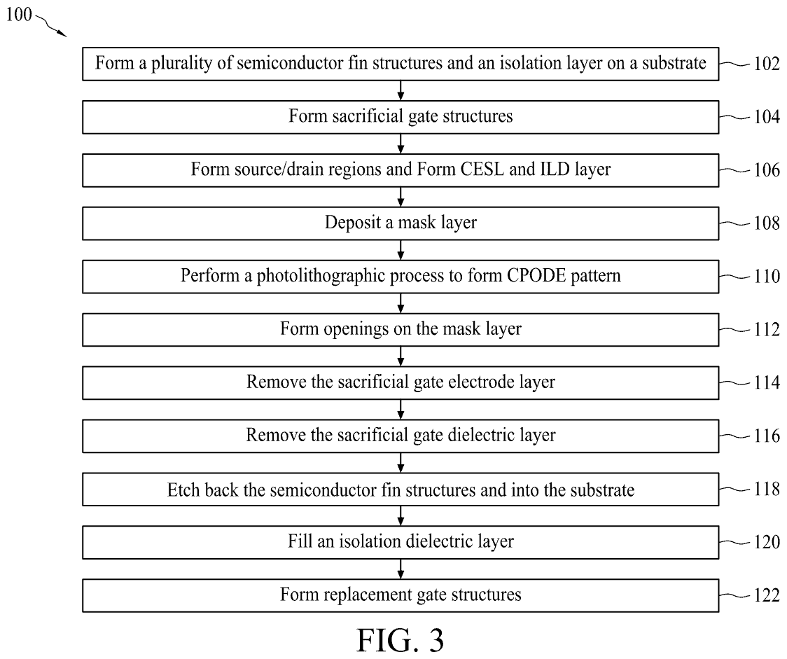

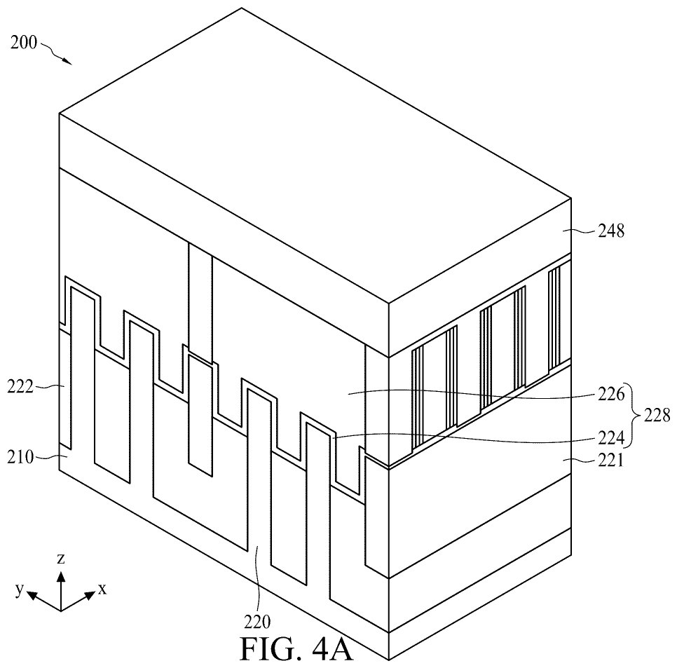

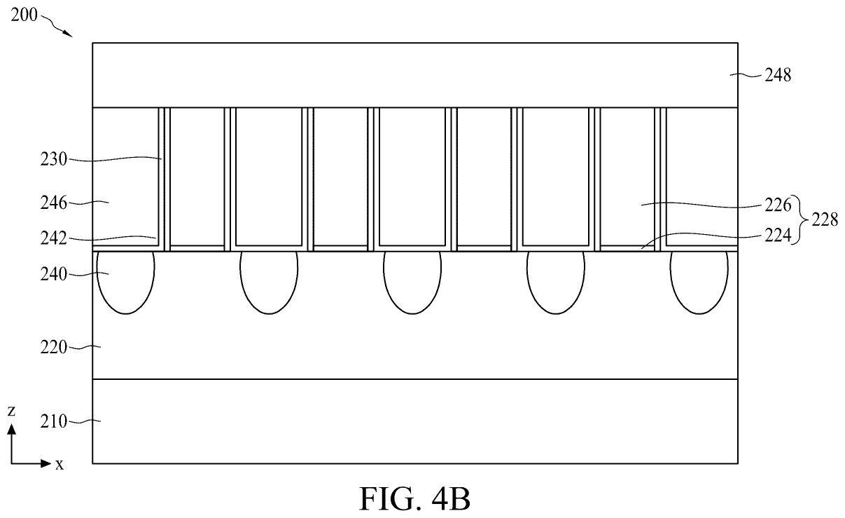

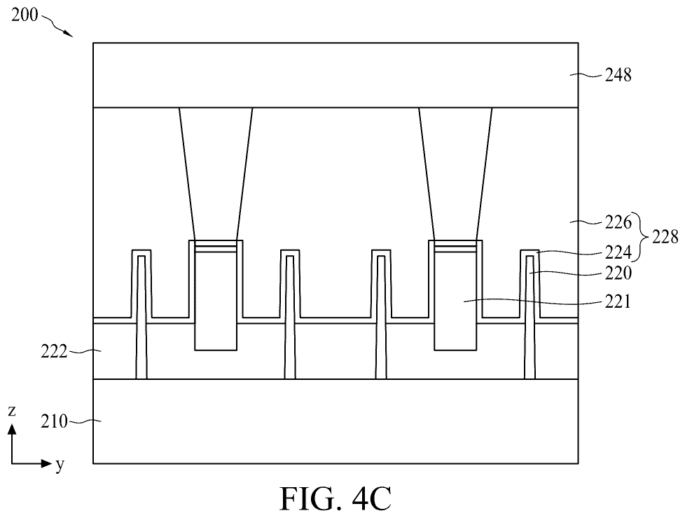

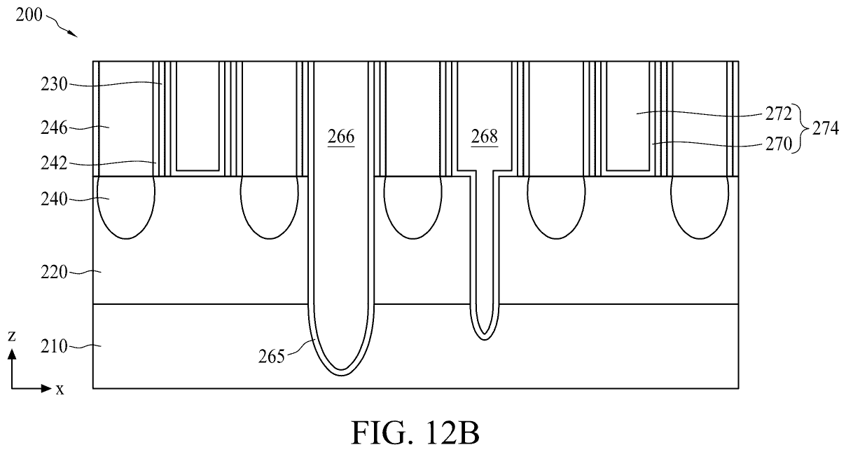

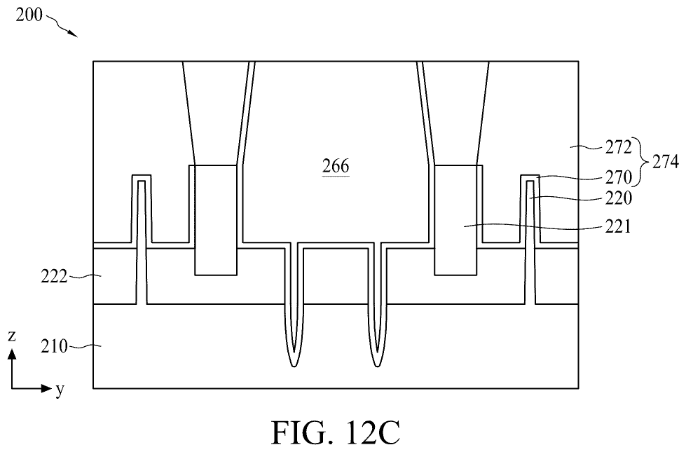

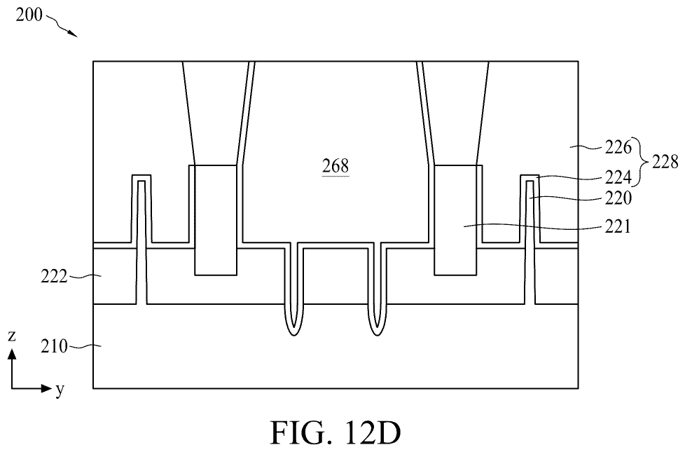

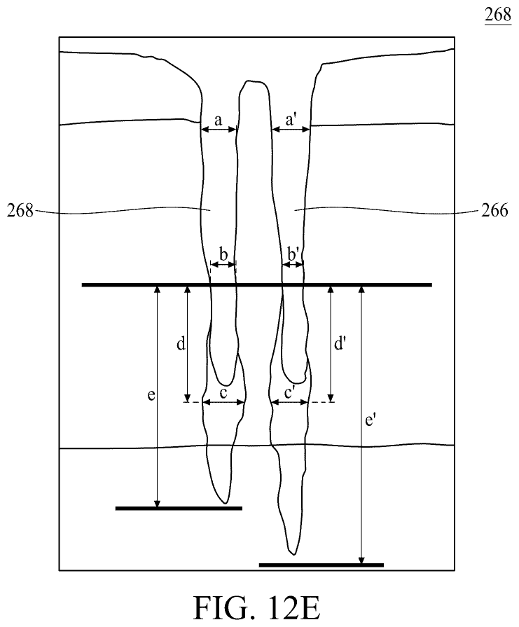

FIG. 3 is a flow chart of a method 100 for manufacturing of a semiconductor device according to embodiments of the present disclosure. FIGS. 4A-4C and 12A-12C schematically illustrate various stages of manufacturing a semiconductor device 200 according to embodiments of the present disclosure. The semiconductor device 200 may include isolation structures similar to the semiconductor devices 10, and 10a-101.

The method 100 begins at operation 102 where a plurality of semiconductor fins 220 are formed over a substrate 210, as shown in FIGS. 4A, 4B, and 4C. FIG. 4A is a schematic perspective view of the semiconductor device 200. FIG. 4B is a cross-sectional view of the semiconductor device 200 along the x-direction. FIG. 4C is a schematic cross-sectional view of the semiconductor device 200 along the y-direction.

The substrate 210 may include a single crystalline semiconductor material such as, but not limited to Si, Ge, SiGe, GaAs, InSb, GaP, GaSb, InAlAs, InGaAs, GaSbP, GaAsSb, and InP. The substrate 210 may include various doping configurations depending on circuit design. For example, different doping profiles, e.g., n-wells, p-wells, may be formed in the substrate 210 in regions designed for different device types, such as n-type field effect transistors (NFET), and p-type field effect transistors (PFET). In some embodiments, the substrate 210 may be a silicon-on-insulator (SOI) substrate including an insulator structure for enhancement.

Semiconductor fins 220 are formed on and in the substrate 210. The semiconductor fins 220 may be formed by patterning a hard mask deposited on the semiconductor stack and one or more etching processes. The semiconductor fins 220 are formed along the x-direction.

An isolation layer 222 is then formed in the trenches between the semiconductor fins 220. The isolation layer 222 may be formed by a high-density plasma chemical vapor deposition (HDP-CVD), a flowable CVD (FCVD), or other suitable deposition process. In some embodiments, the isolation layer 222 may include silicon oxide, silicon nitride, silicon oxynitride, fluorine-doped silicate glass (FSG), a low-k dielectric, combinations thereof. In some embodiments, the isolation layer is formed to cover the semiconductor fins 220 by a suitable deposition process, such as atomic layer deposition (ALD), and then recess etched using a suitable anisotropic etching process to expose the channel portions 218 of the semiconductor fins 220.

In some embodiments, dielectric fins 221 may be formed between the semiconductor fins 220. The dielectric fins 221 may be formed during deposition and etching back of the isolation layer 222.

In operation 104, sacrificial gate structures 228 and spacer layers 230 are then formed over the semiconductor fins 220, as shown in FIGS. 4A-4C. A sacrificial gate dielectric layer 224 is deposited over the exposed surfaces of the semiconductor device 200. The sacrificial gate dielectric layer 224 may be formed conformally over the semiconductor fins 220, and the isolation layer 222. In some embodiments, the sacrificial gate dielectric layer 224 may be deposited by a CVD process, a sub-atmospheric CVD (SACVD) process, a FCVD process, an ALD process, a PVD process, or other suitable process. The sacrificial gate dielectric layer 224 may include one or more layers of dielectric material, such as SiO₂, SiN, a high-K dielectric material, and/or other suitable dielectric material.

A sacrificial gate electrode layer 226 is deposited over the sacrificial gate dielectric layer 224. The sacrificial gate electrode layer 226 may be blanket deposited over the sacrificial gate dielectric layer 224. The sacrificial gate electrode layer 226 includes silicon such as polycrystalline silicon or amorphous silicon. In some embodiments, the sacrificial gate electrode layer 226 is subjected to a planarization operation. The sacrificial gate electrode layer 226 may be deposited using CVD, including LPCVD and PECVD, PVD, ALD, or other suitable process. A patterning operation is then performed over the sacrificial gate dielectric layer 224 and the sacrificial gate electrode layer 226 to form the sacrificial gate structures 228, which cover over portions of the semiconductor fins 220 designed to be channel regions.

Gate sidewall spacers 230 are then formed on sidewalls of each sacrificial gate structures 228. After the sacrificial gate structures 228 are formed, the gate sidewall spacers 230 may be formed by a blanket deposition of an insulating material followed by anisotropic etch to remove insulating material from horizontal surfaces. The gate sidewall spacers 230 may have a thickness in a range between about 3 nm and about 8 nm. In some embodiments, the insulating material of the gate sidewall spacers 230 is a silicon nitride-based material, such as SIN, SiON, SiOCN or SiCN and combinations thereof. In FIG. 3A, the gate sidewall spacers 230 include two layers. In other embodiments, the gate sidewall spacers 230 may be formed from less or more layers of dielectric materials.

In operation 106, the semiconductor fins 220 are etched back and source/drain regions 240 are grown from exposed semiconductor fins 220, as shown in FIGS. 4A-4C. The source/drain regions 240 are formed by an epitaxial growth method using CVD, ALD or molecular beam epitaxy (MBE). The source/drain regions 240 may include one or more layers of Si, SiP, SiC and SiCP for NFET or Si, SiGe, Ge for a PFET. For the PFET, p-type dopants, such as boron (B), may also be included in the source/drain regions 240.

A contact etch stop layer (CESL) 242 and an interlayer dielectric (ILD) layer 244 are formed over the exposed surfaces. The CESL 242 is formed on the epitaxial source/drain regions 240 and the gate sidewall spacers 230. The CESL 242 may include Si₃N₄, SiON, SiCN or any other suitable material, and may be formed by CVD, PVD, or ALD. The interlayer dielectric (ILD) layer 244 is formed over the contract etch stop layer (CESL) 242. The materials for the ILD layer 244 include compounds comprising Si, O, C, and/or H, such as silicon oxide, SiCOH and SiOC. Organic materials, such as polymers, may be used for the ILD layer 244. After the ILD layer 244 is formed, a planarization operation, such as CMP, is performed to expose the sacrificial gate electrode layer 226 for subsequent removal of the sacrificial gate structures 228. The ILD layer 244 protects the epitaxial source/drain regions 240 during the removal of the sacrificial gate structures 228.

In operation 108, a mask layer 248 is deposited on the semiconductor device 200, as shown in FIGS. 4A-4C. The mask layer 248 may include in one or more dielectric layer. The mask layer 248 may be deposited over the sacrificial gate structure 228, the gate spacers 230, the CESL 242, and ILD layer 244. In some examples, the one or more mask layers may include or be silicon nitride, silicon oxynitride, silicon carbide, silicon carbon nitride, the like, or a combination thereof, and may be deposited by CVD, PVD, ALD, or another deposition technique. In some embodiments, the mask layer 248 may be a film with compressed stress because openings formed in the compressed stress film may not gap. In some embodiments, the mask layer 248 may be a silicon nitride having a thickness in a range between about 650 angstroms and 850 angstroms, for example between about 730 angstroms and about 750 angstroms.

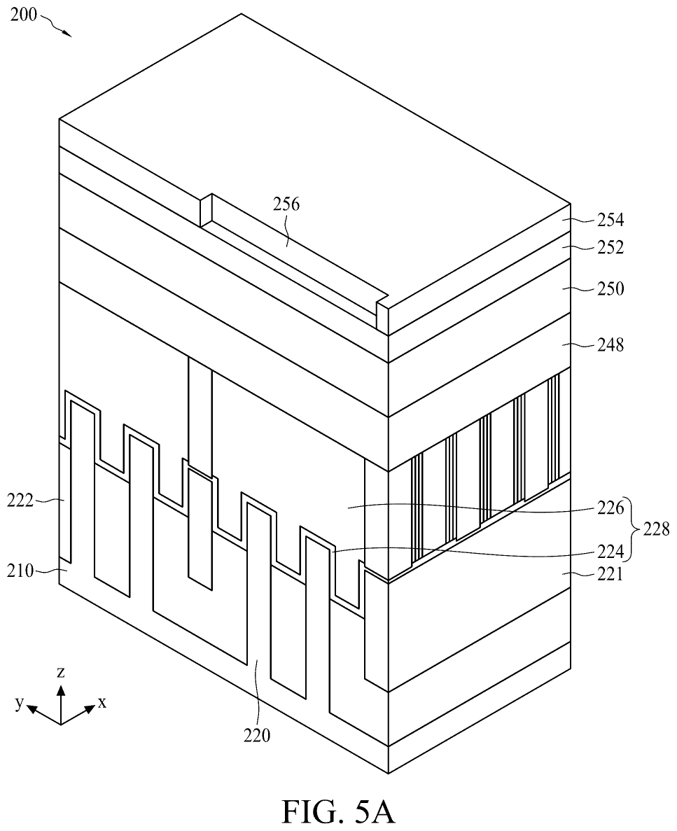

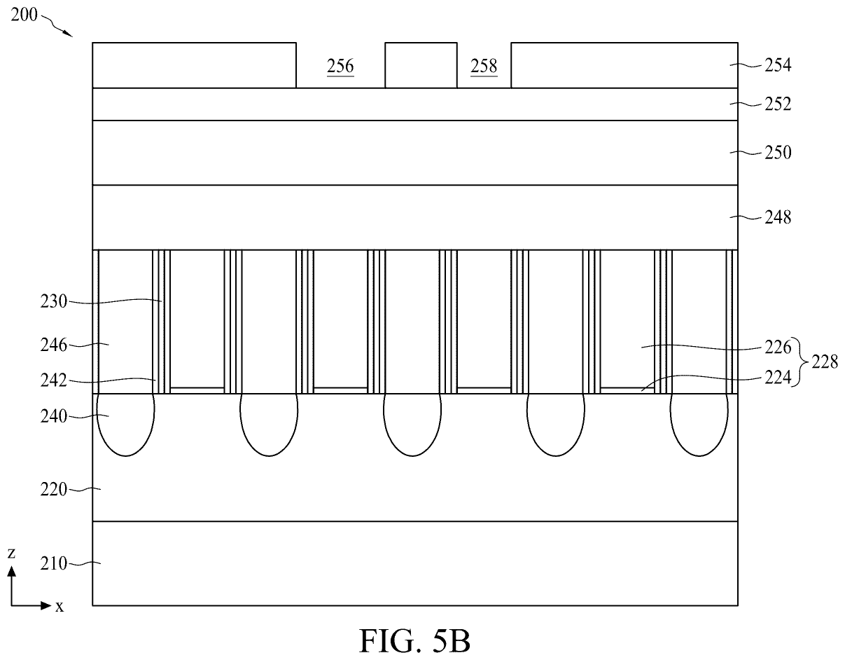

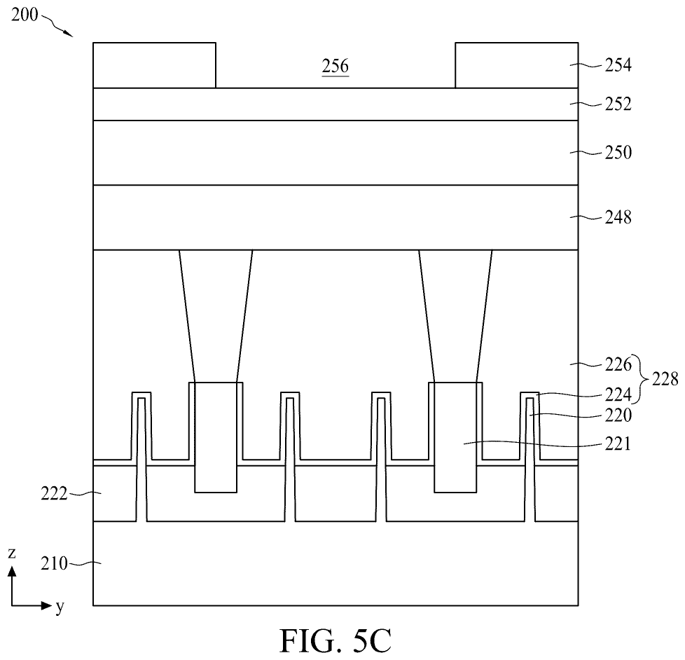

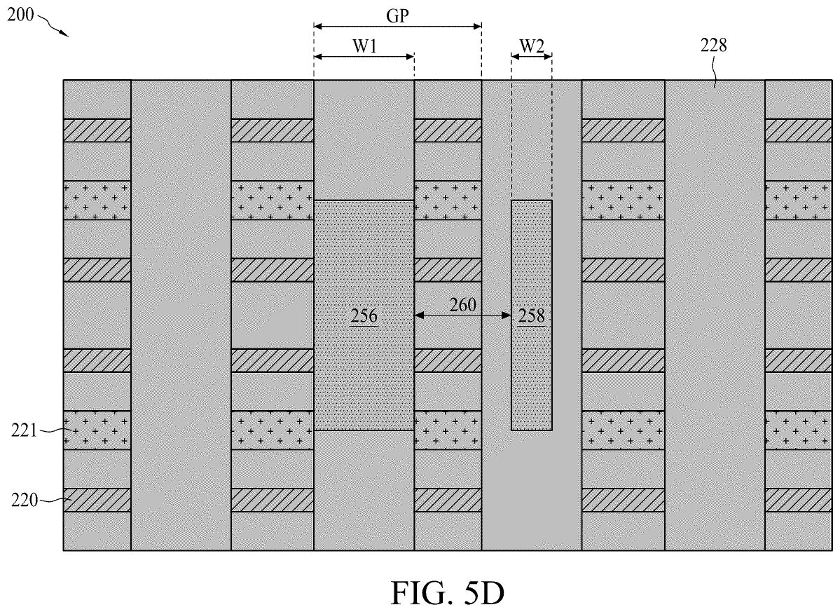

In operation 110, a photolithographic process is performed to form a CPODE pattern in a photoresist layer, as shown in FIGS. 5A-5D. FIG. 5A is a schematic perspective view of the semiconductor device 200. FIG. 5B is a cross-sectional view of the semiconductor device 200 along the x-direction. FIG. 5C is a schematic cross-sectional view of the semiconductor device 200 along the y-direction. FIG. 5D is a schematic top view of the semiconductor device 200. In some embodiments, a tri-layer photoresist stack including a bottom layer 250, a back anti-reflection coating (BARC) 252, and a photo resist (PR) layer 254 are deposited. A lithographic process is performed to form a CPODE pattern.

In some embodiments, the CPODE pattern may include wide openings 256 and narrow openings 258 in alignment with the sacrificial gate structures 230. The wide openings 256 is shaped to form a wide segment of the isolation structures 20 discussed above. The narrow openings 258 is shaped to form a narrow segment of the isolation structures 20. The wide openings 256 and the narrow openings 258 may be arranged in a pattern to achieve isolation across semiconductor fins 220. The wide openings 256 and narrow openings 258 may be arranged in any patterns in the semiconductor devices 10, and 10a-101. In some embodiments, the wide opening 256 may have a width W1 along the x-direction and the narrow opening 458 may have a width W2 along the x-direction.

As shown in FIG. 5D, the wide opening 256 and the narrow opening 258 are positioned along two neighboring sacrificial structures 228. By positing the wide opening 256 is positioned next to the narrow opening 258, a spacing 260 between the openings 256, 258 may be maintained at a dimension to avoid photoresist defects, such as peeling.

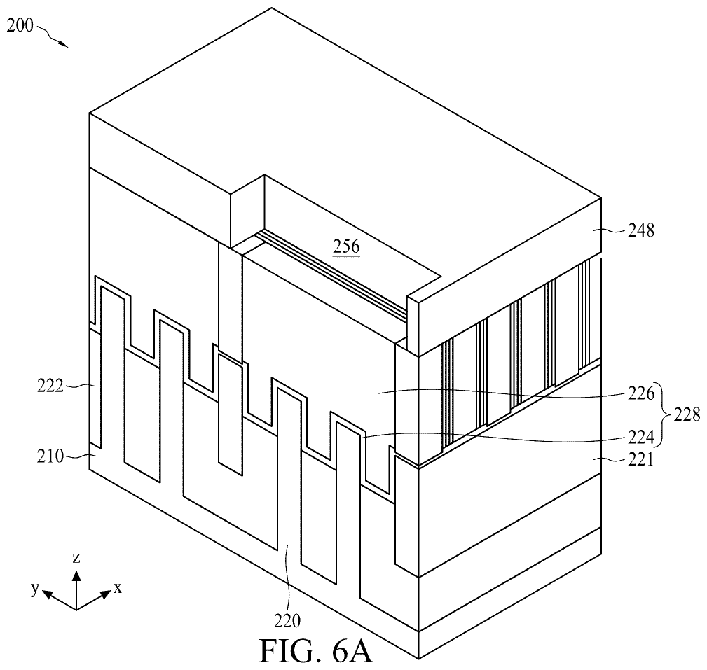

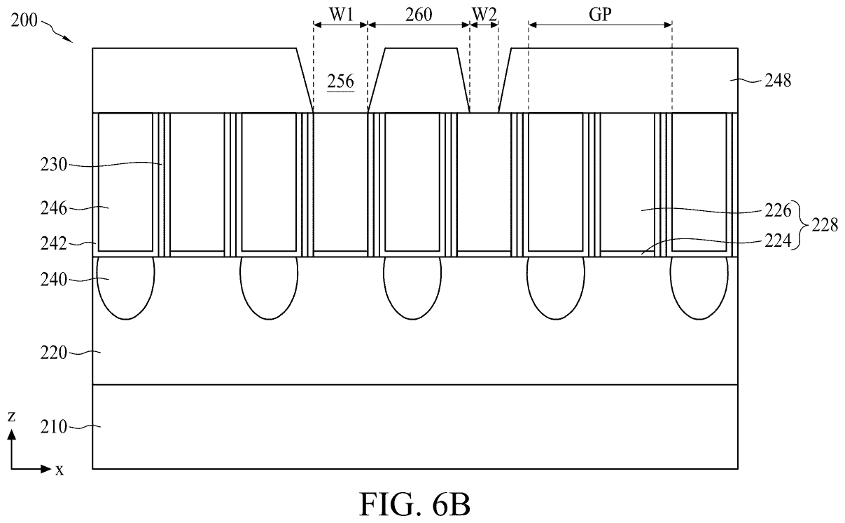

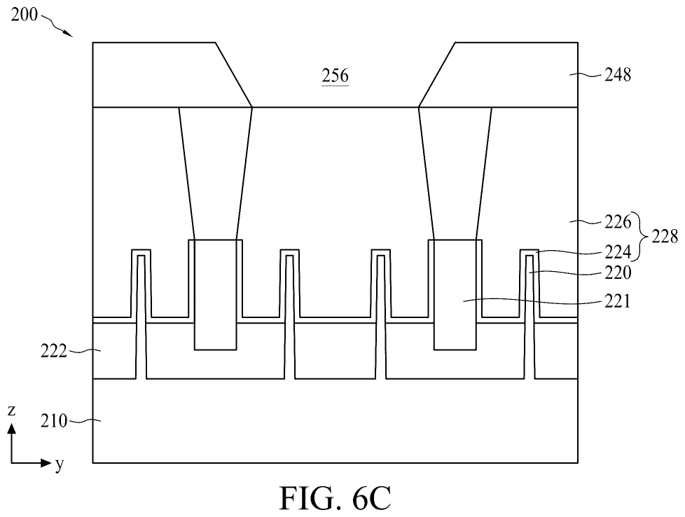

In operation 112, the CPODE pattern is transferred to the mask layer 248, as shown in FIGS. 6A-6C. FIG. 6A is a schematic perspective view of the semiconductor device 200. FIG. 6B is a cross-sectional view of the semiconductor device 200 along the x-direction. FIG. 6C is a schematic cross-sectional view of the semiconductor device 200 along the y-direction. In some embodiments, the CPODE pattern may be transferred to the mask layer 248 by a suitable etch process. After operation 112, portions of the sacrificial gate structures 228 are exposed. As shown in FIG. 6B, the wide opening 256 in the mask layer 248 may be wider than the sacrificial gate electrode layer 226 along the x-direction while the narrow opening 258 in the mask layer 248 may expose a portion of the sacrificial gate electrode layer 226.

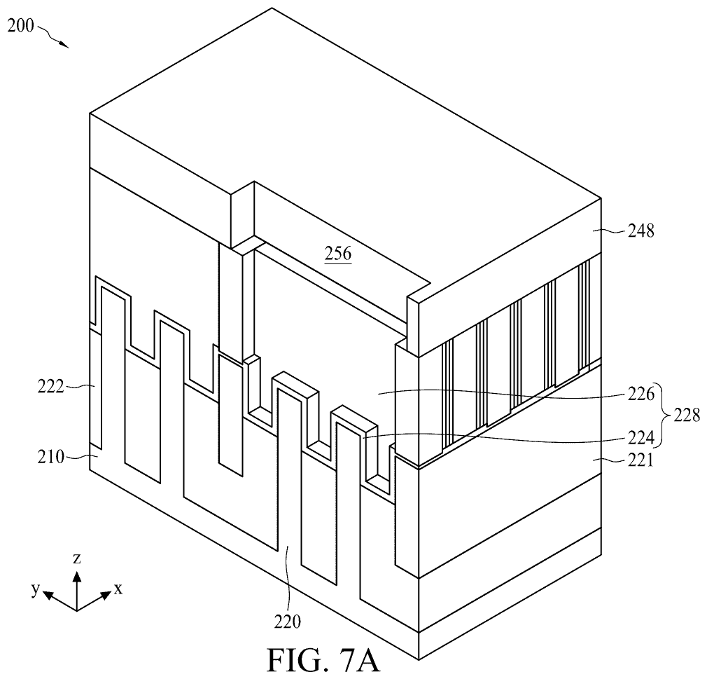

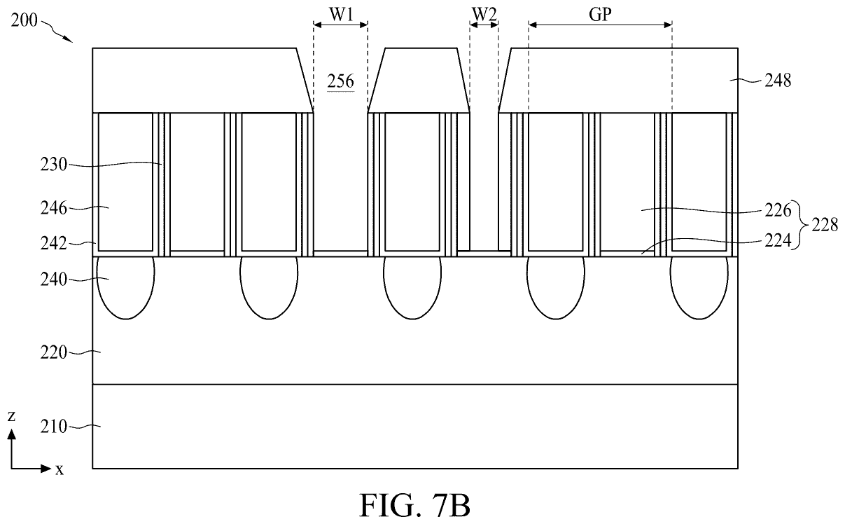

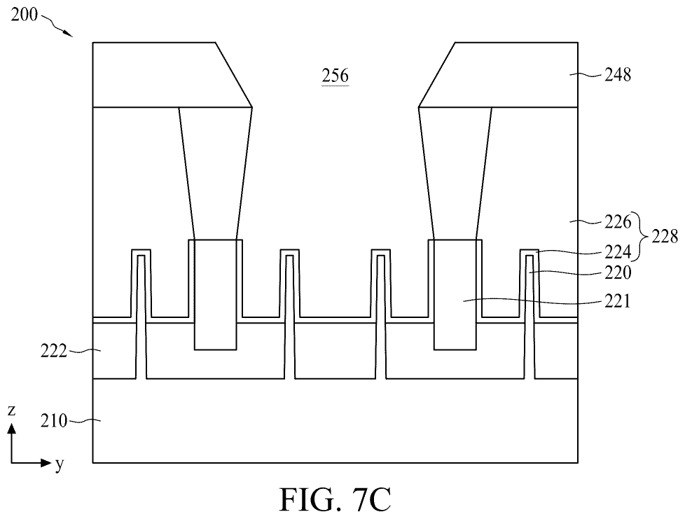

In operation 114, an etch process is performed to selectively remove the sacrificial gate electrode layer 226, as shown in FIGS. 7A-7C. In some embodiments, when the sacrificial gate electrode layer 226 is polysilicon, a wet etchant such as a Tetramethylammonium hydroxide (TMAH) solution can be used to selectively remove the sacrificial gate electrode layer 226 without removing the dielectric materials of the ILD layer 242, the CESL 244, and the sidewall spacers 230. As shown in FIG. 7B, under the wide opening 256 in the mask layer 248, the sacrificial gate electrode layer 226 may be substantially removed exposing the gate spacers 230. Under the narrow opening 258 in the mask layer 248, the sacrificial gate electrode layer 226 may be partially removed without exposing the gate spacers 230.

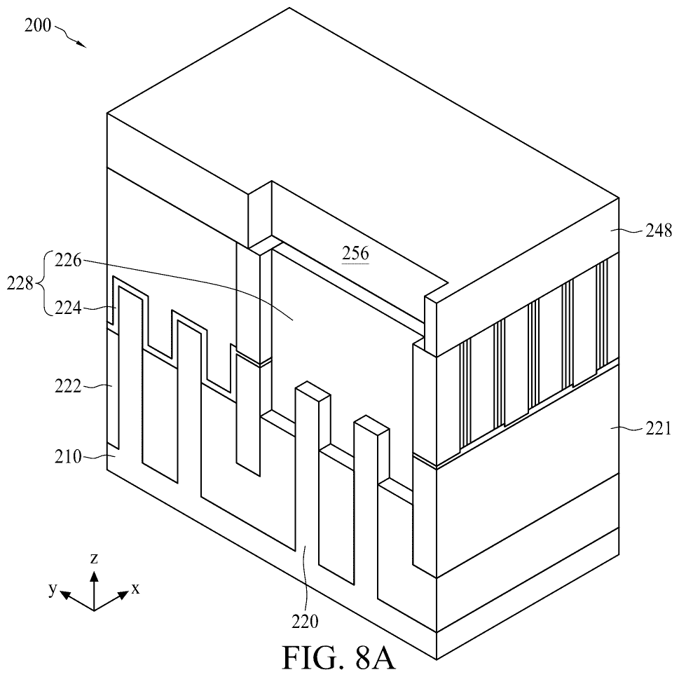

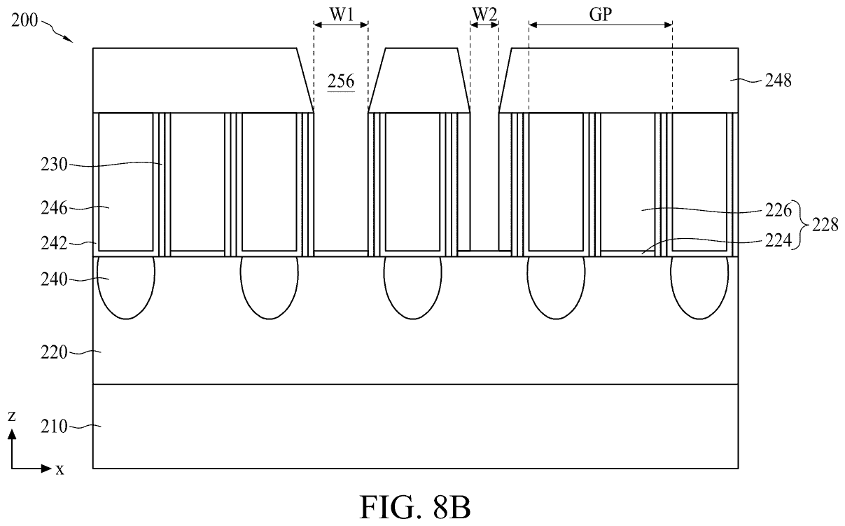

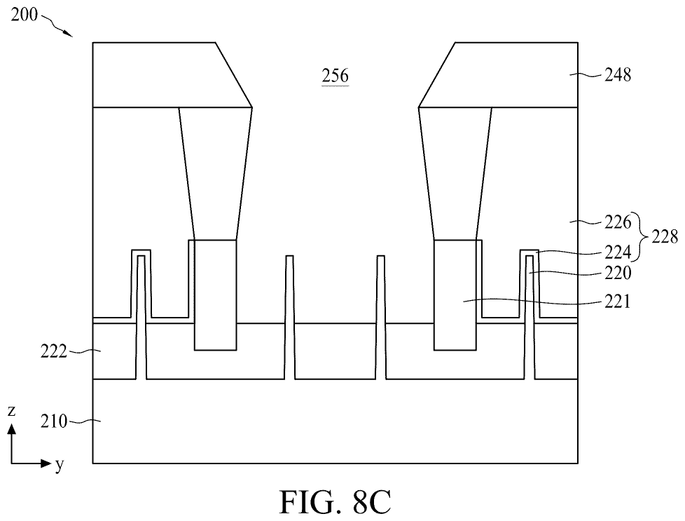

In operation 116, an etch process is performed to remove the sacrificial gate dielectric layer 224, as shown in FIGS. 8A-8C. The sacrificial gate dielectric layer 224 may be removed by any suitable etching process, such as plasma dry etching and/or wet etching. After operation 116, the semiconductor fins 220 exposed through the openings 256, 258 are exposed. As shown in FIG. 8B, under the wide opening 256 in the mask layer 248, the sacrificial gate dielectric layer 224 may be substantially removed. Under the narrow opening 258 in the mask layer 248, the sacrificial gate dielectric layer 224 may be partially removed and a portion of the sacrificial gate dielectric layer 224 remains on the semiconductor fins 220.

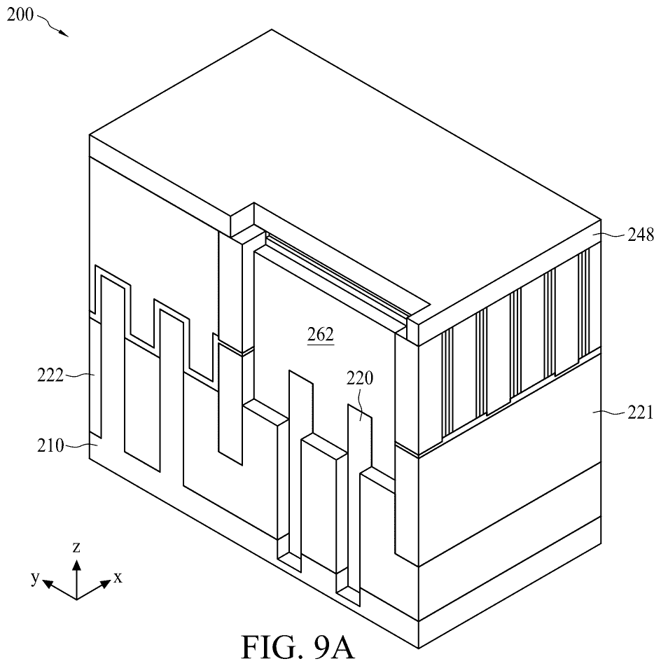

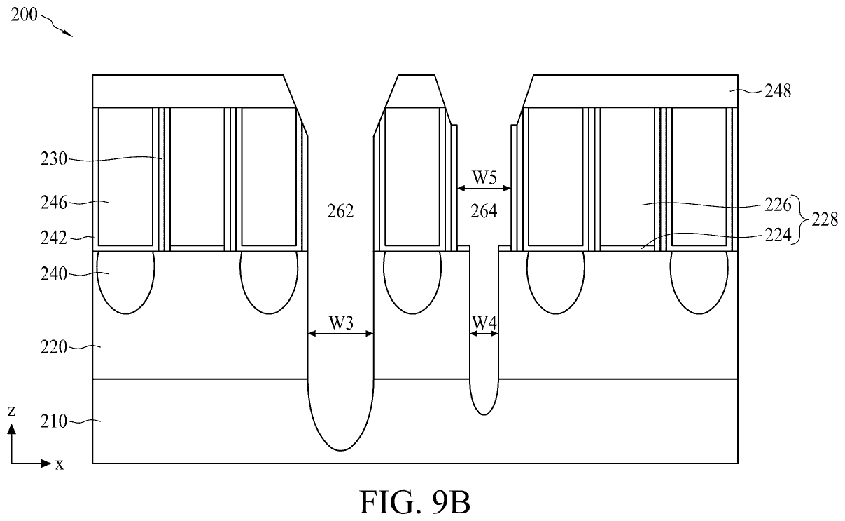

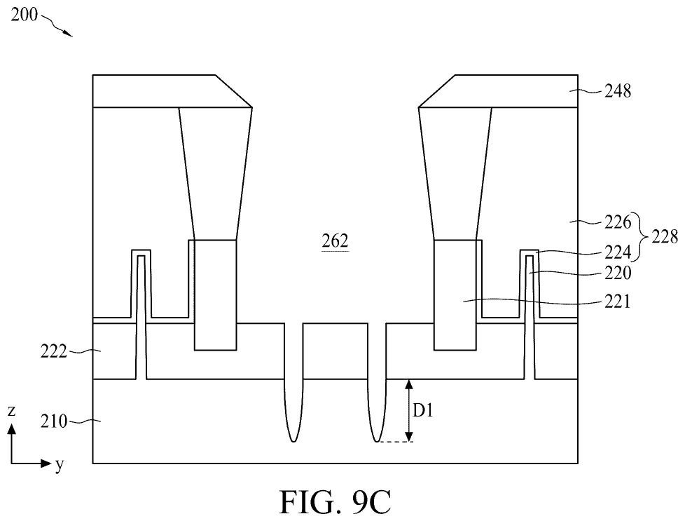

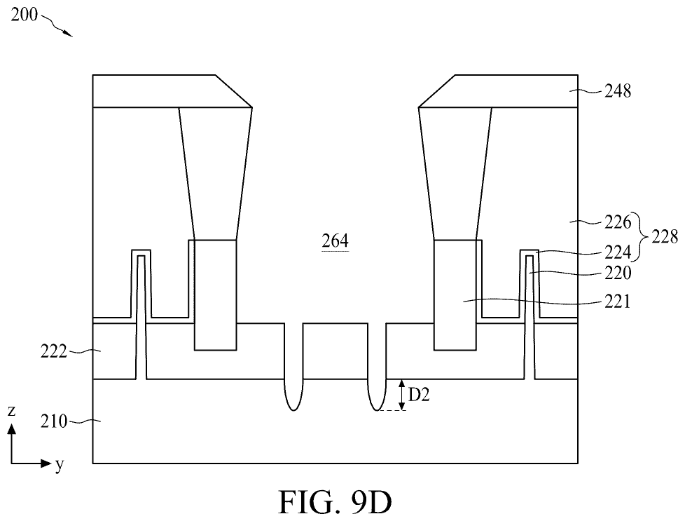

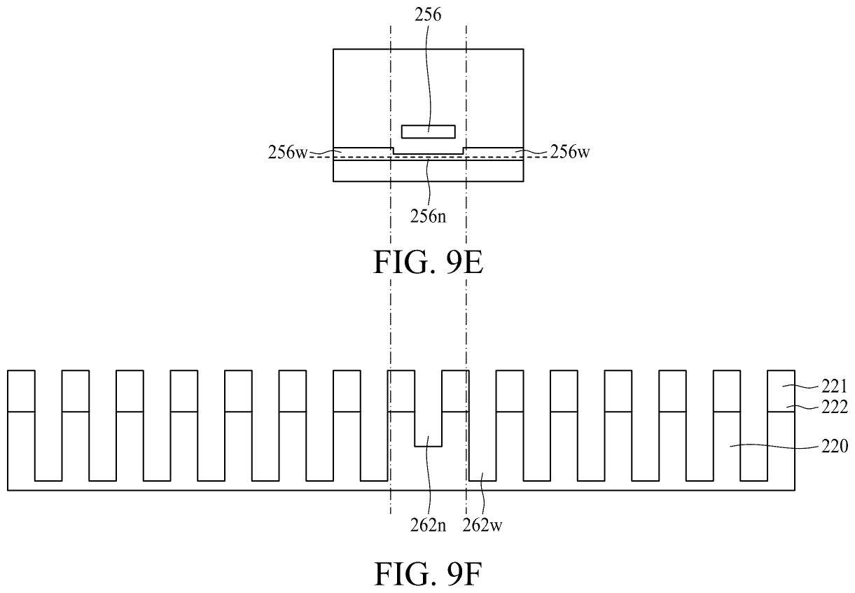

In operation 118, an etch process is performed to remove the semiconductor fin 220 and into the semiconductor substrate 210 and form isolation openings 262, 264, as shown in FIGS. 9A-9C. The etch process may include one or more plasma etch operations configured to selectively remove semiconductor materials to form self-aligned CPODE openings in the semiconductor substrate 210. In some embodiments, the self-aligned etch process may be performed by one or more plasma etching.

In some embodiments, the etch process can be achieved through HBr based plasma etch. In some embodiments, O₂ or CO₂ may be added to HBr. In some embodiments, a polymer protection layer may be deposited on top of the hard mask layer 248 in the beginning of the etch process to increase the etch selectivity of semiconductor material, such as silicon, over materials in hard mask layer 248, such as SiN. Additionally, passivation layer may be formed during the etch processes to facilitate the self-aligned etch process. In some embodiments, the passivation layer may be silicon oxide based. In some embodiments, the passivation process may be formed using precursors containing SiCl₄, O₂, and HBr. In some embodiments, a break-through operation may be performed to remove excessive passivation layers. In some embodiments, the break-through operation may be an etch process based on a fluorine containing etchant, such as CF₄, CHF₃, CH₂F₂, CHF₃, C₄F₆, or a combination thereof.

In some embodiments, the plasma etch process may be high density plasma process. The etch process may be performed using processing chambers with an ICP (inductive coupled plasma) or resonant antenna plasma source. The plasma may be driven by an RF power generator using AC electrical current operating on a frequency of multiple of 13.56 MHz and 27 MHz. The process chamber may be operated at a pressure in a range of about 1 mTorr to about 200 mTorr. The etch process may be performed at a temperature range between about 10 degrees Celsius to about 200 degrees Celsius. The RF power generator may be operated at a power level between about 0 W to about 2500 W. In some embodiments, an RF bias power may be applied to a substrate pedestal in the process chamber. The RF bias power may be in a range of about 0 W to about 2000 W. In some etching operation, the etch plasma may be pulsed with a duty cycle in a range of about 5% to 95%. In some embodiments, the plasma operation may be performed with only bias power, i.e., with zero plasma power, to enhance etch directionality.

After operation 118, the isolation openings 262, 264 are formed through the wide opening 256 and narrow opening 258 in the mask layer 248 respectively. As shown in FIGS. 9B, 9C, and 9D, the isolation opening 262 extends into the semiconductor substrate 210 deeper than the isolation opening 264, which is caused by width difference between the openings 256 and 258. The opening 262 may have a depth D1 below the isolation layer 222 along the z-direction. The opening 264 may have a depth D2 below the isolation layer 222 along the z-direction. The depth D1 is greater than the depth D2.

The opening 262 may have a width W3 below a top of the semiconductor fin 220 along the x-direction. The width W3 is substantially similar to the width W1. The opening 262 may have a width W4 below the top of the semiconductor fin 220 and a width W5 above the top of the semiconductor fin 220 along the x-direction. The width W3 is greater than the width W4. In some embodiments, the width W5 is greater than W4 because the sacrificial gate electrode layer 224 above the top of the semiconductor fin 220 may be removed during operation 118.

In some embodiments, when a mask opening includes wide and narrow segments, the depth of the CPODE opening into the semiconductor substrate may vary as shown in FIGS. 9E and 9F. FIG. 9E is a schematic top view of a CPODE pattern with a combination opening having two wide segments 256w connected by a narrow segment 256n. FIG. 9F is a schematic cross-sectional view of a fin structure 220 under the combination opening 262n and 262w. The opening 262n under than the narrow segment 256n is shallower than the opening 262w under the wide segment 256w.

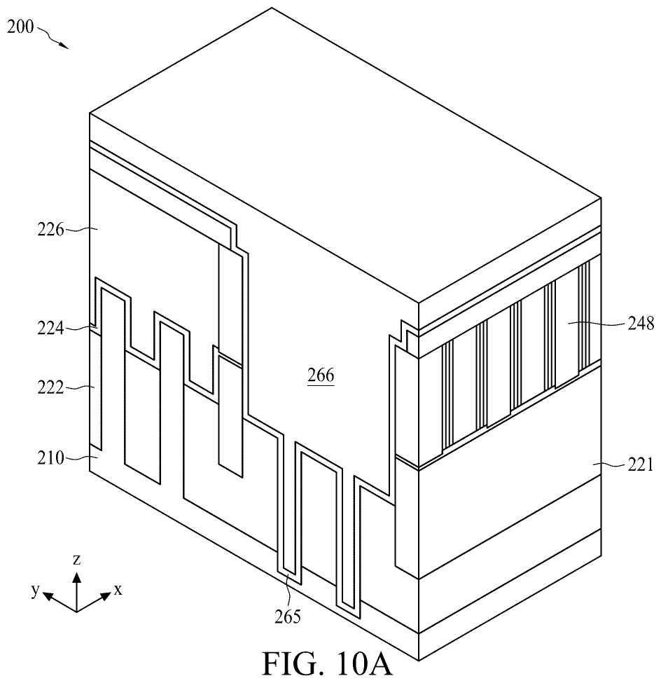

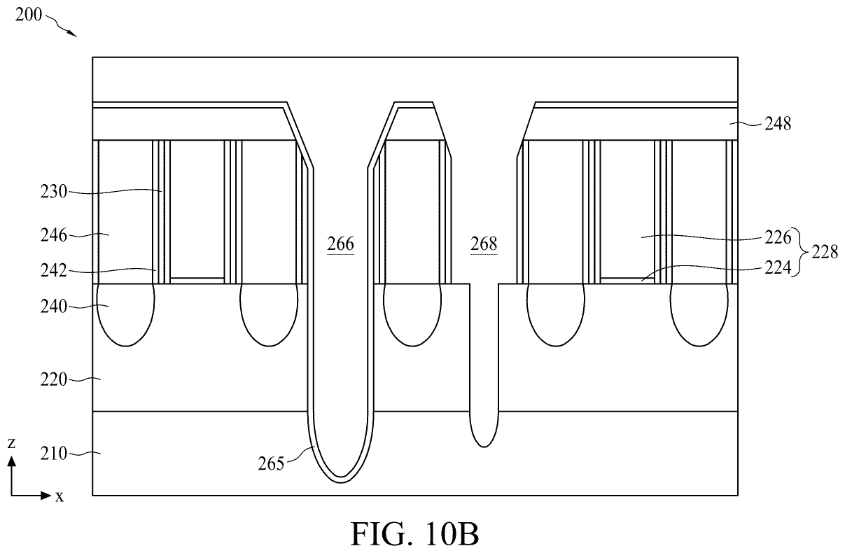

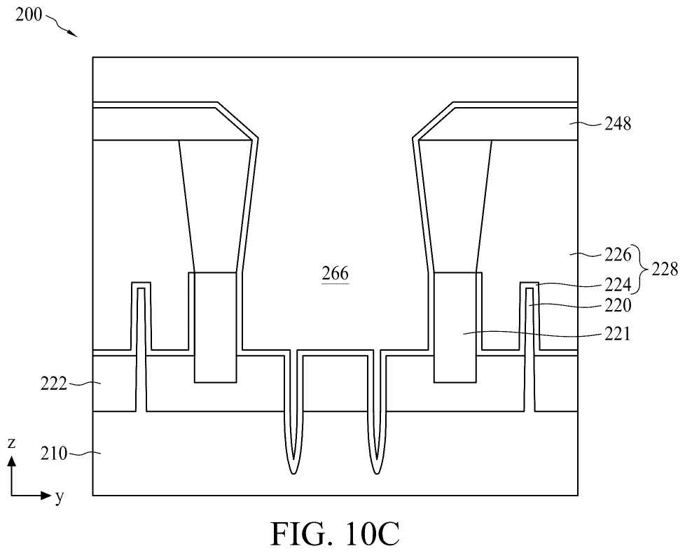

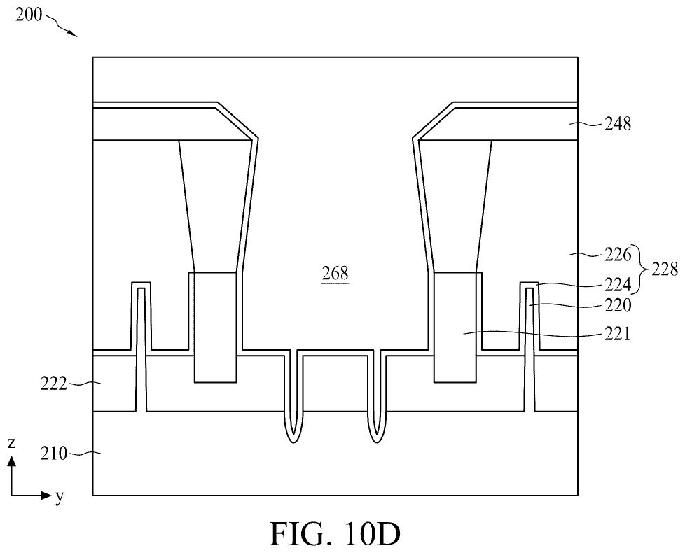

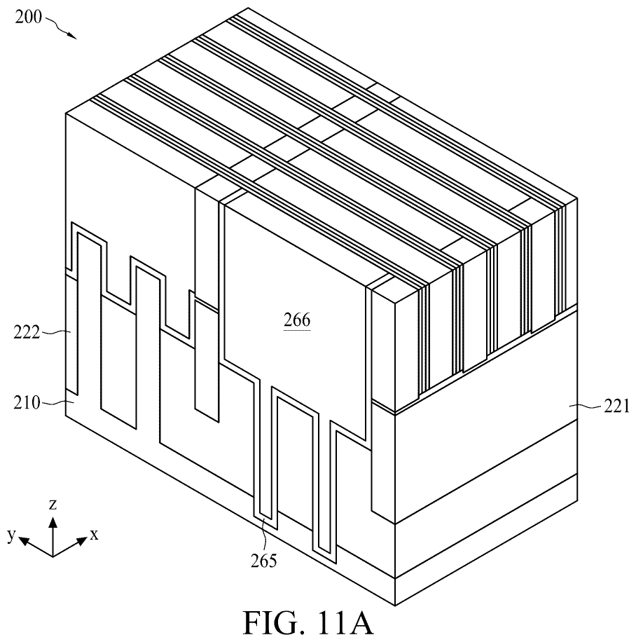

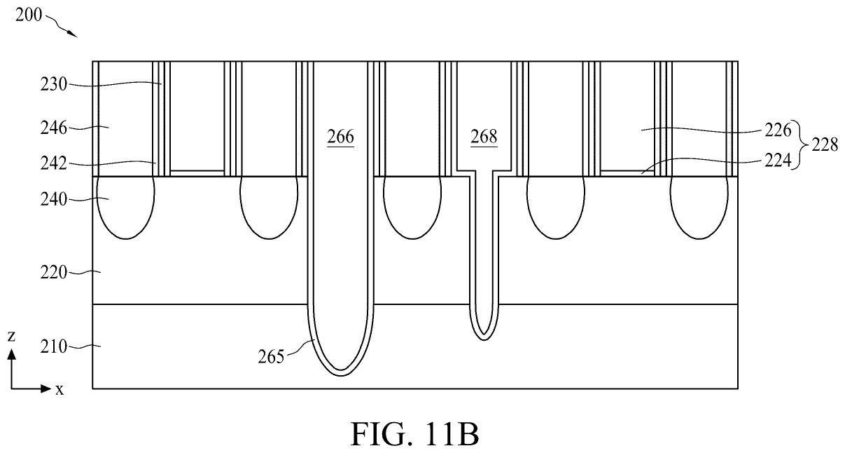

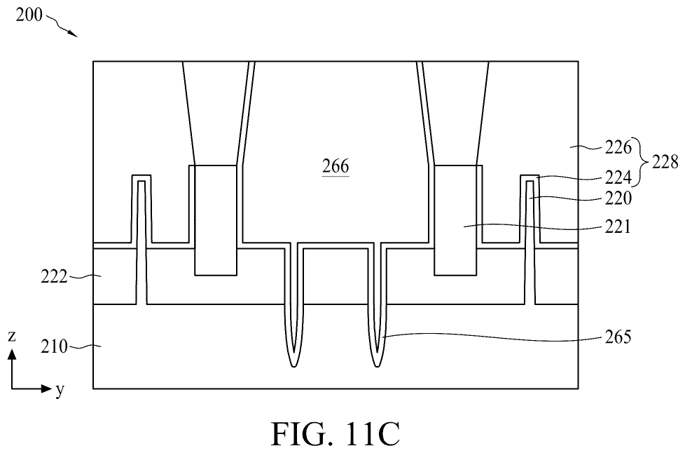

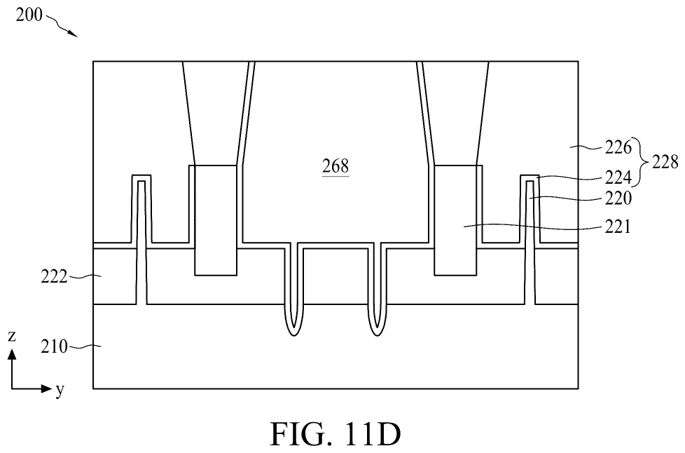

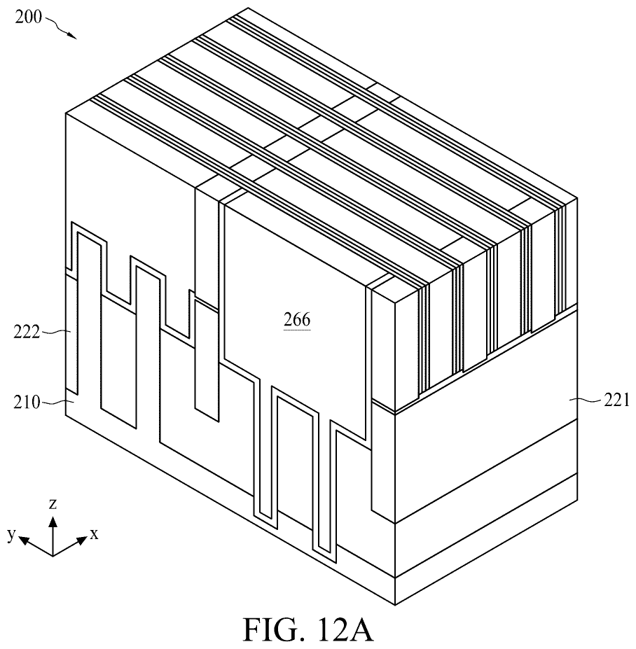

In operation 120, the openings 262 and 264 are filled with isolation material to form isolation structures 266, 268, as shown in FIGS. 10A-10D and 11A-11D. In some embodiments, a fill material is deposited in the openings 262, 264 in place of the removed semiconductor substrate 210, the semiconductor fins 220, and the section of the sacrificial gate structure 230. The fill material may be an insulating material. In some examples, the fill material may be a single insulating material, and in other examples, the fill material may include multiple different insulating materials, such as in a multi-layered configuration. The fill material may include or be silicon oxide, silicon nitride, silicon oxynitride, silicon carbide, silicon carbon nitride, the like, or a combination thereof, and may be deposited by CVD, PVD, ALD, or another deposition technique. In some embodiments, a liner layer 265 may be formed prior to depositing the fill material. After depositing the liner layer 265 and the fill material, a CMP process may be performed to expose the sacrificial gate structures 228 for subsequent processes.

The isolation structure 266 extends sufficiently deep into the semiconductor substrate 210 and provides electrical isolation between the source/drain regions 240 at opposing sides.

In operation 122, replacement gate process is performed as shown in FIGS. 12A-12D. The sacrificial gate structures 228 are first removed. Particularly, the sacrificial gate electrode layer 226 and the sacrificial gate dielectric layer 224 are removed sequentially to expose the semiconductor fins 220. The replacement gate structures 274 are then formed around the semiconductor fins 220 A gate dielectric layer 270 is formed on the semiconductor fins 220 and a gate electrode layer 272 is formed on the gate dielectric layer 270. The gate dielectric layer 270 and the gate electrode layer 272 may be referred to as a replacement gate structure 274.

The gate dielectric layer 270 may be formed by CVD, ALD or any suitable method. In one embodiment, the gate dielectric layer 246 is formed using a highly conformal deposition process such as ALD in order to ensure the formation of a gate dielectric layer 270. The gate dielectric layer 270 includes one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate electrode layer 272 is formed on the gate dielectric layer 270. The gate electrode layer 272 includes one or more layers of conductive material, such as polysilicon, aluminum, copper, titanium, tantalum, tungsten, cobalt, molybdenum, tantalum nitride, nickel silicide, cobalt silicide, TIN, WN, TiAl, TiAlN, TaCN, TaC, TaSiN, metal alloys, other suitable materials, and/or combinations thereof. The gate electrode layer 272 may be formed by CVD, ALD, electro-plating, or other suitable method.

FIG. 12E is a schematic cross-sectional view of an example device according to the present disclosure. In the device of FIG. 12E, there are two isolation structures 266, 268. The isolation structure 266 is formed from a wider mask opening and the isolation structure 268 is formed from a narrow mask opening. The isolation structure 268 has an average mask opening width a about 28.1 nm, an average fin top width b about 18.7 nm, an average bowing width (maximum width) c about 28.7 nm, average bowing depth d about 75.3 nm, and average depth e about 147.3 nm. The isolation structure 266 has an average mask opening width a′ about 31.5 nm, an average fin top width b′ about 18.4 nm, an average bowing width (maximum width) c′ about 31.5 nm, average bowing depth d′ about 75.3 nm, and average depth e′ about 169.1 nm.

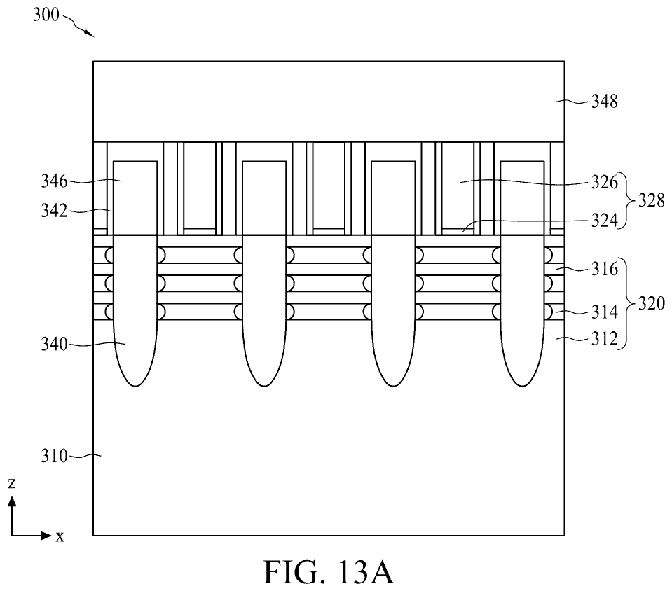

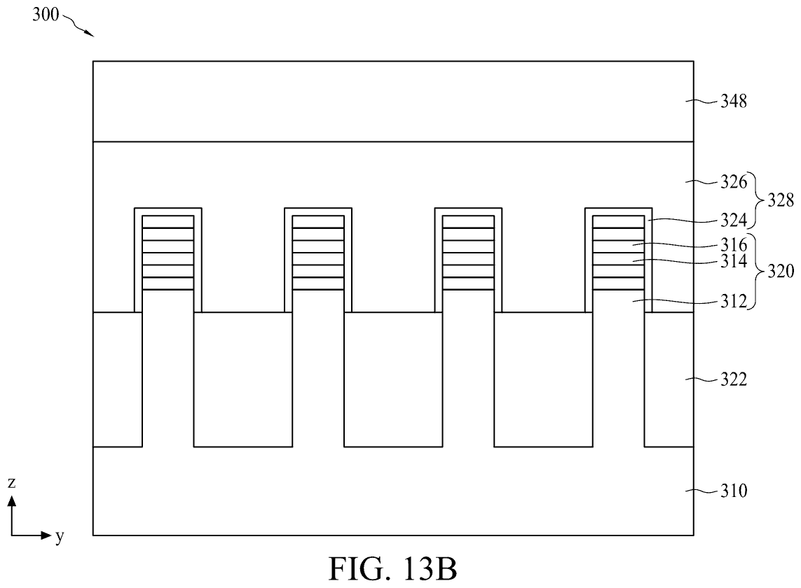

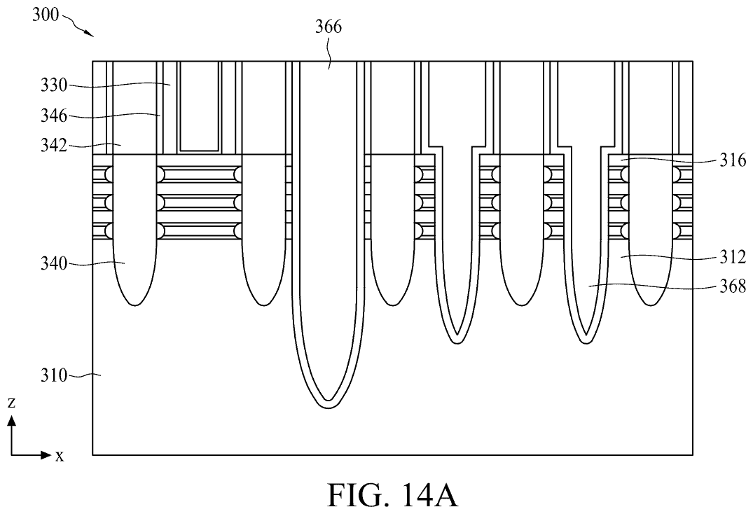

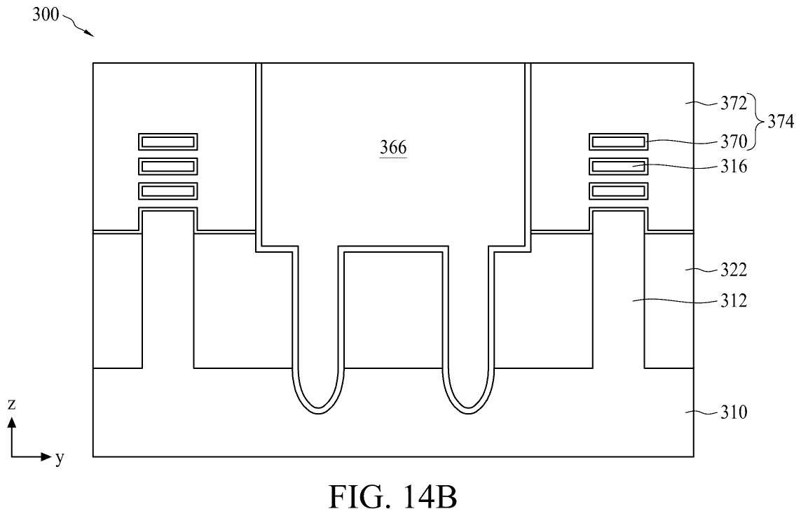

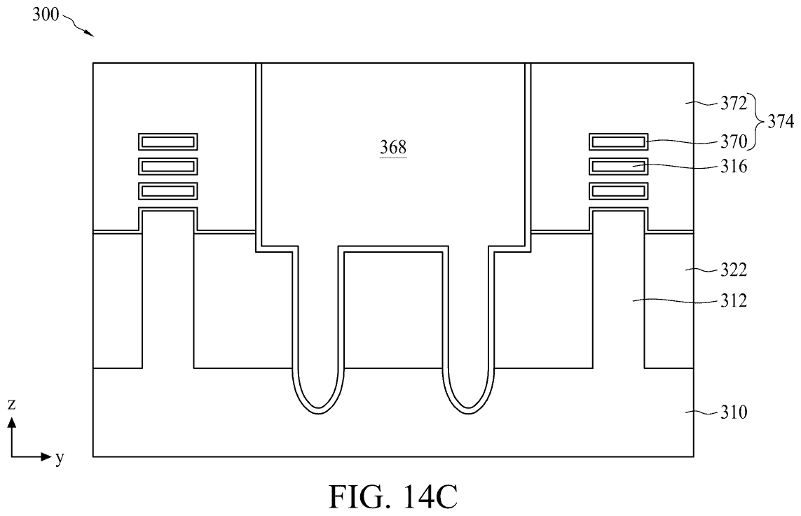

The semiconductor device 200 is a FinFET device. The method 100 may be used to fabricate a GAA device as well. FIGS. 13A-13B and FIGS. 14A-14C schematically demonstrates a GAA device 300 fabricated using the method 100.

FIGS. 13A-13B schematically demonstrate the GAA device 300 after operation 108. As shown in FIGS. 13A and 13B, the GAA device 300 includes a plurality of semiconductor fins 320 formed over a semiconductor substrate 310. Each of the semiconductor fins 320 includes a well portion 312 formed from the semiconductor substrate 310 and a semiconductor stack including alternatively stacked sacrificial semiconductor layers 314 and semiconductor channel layers 316. Sacrificial gate structures 328 are formed over the semiconductor fins 320. The sacrificial gate structures 328 includes a sacrificial gate dielectric layer 324 and a sacrificial gate electrode layer 326. Sidewall spacers 330 are formed on sidewalls of the sacrificial gate structures 328. Inner spacers 332 are formed on ends of the sacrificial semiconductor layers 314. Epitaxial source/drain regions 340 are formed between the semiconductor channel layers 316. An CESL 342 is formed over the epitaxial source/drain regions 340 and an ILD layer 346 is formed over the CESL 342. A mask layer 348 is deposited on the sacrificial gate structures 328 and the ILD layer 346. The mask layer 348 is used to form a CPODE pattern.

FIGS. 14A-14C schematically demonstrate the GAA device 300 after operation 122. As shown in FIGS. 14A-14C, deep isolation structures 366 and shallow isolation structures 368 are formed in sections of the sacrificial gate structures 328 and into the semiconductor substrate 310. Replace gate structures 374, which includes a gate dielectric layer 370 and a gate electrode layer 372, are formed around the semiconductor channel layers 316. The deep isolation structures 366 formed from a wide opening through the mask layer 348 provides electric isolation between the source/drain regions 340. The shallow isolation structures 368 provide pattern balance and prevent pattern loading during fabrication.

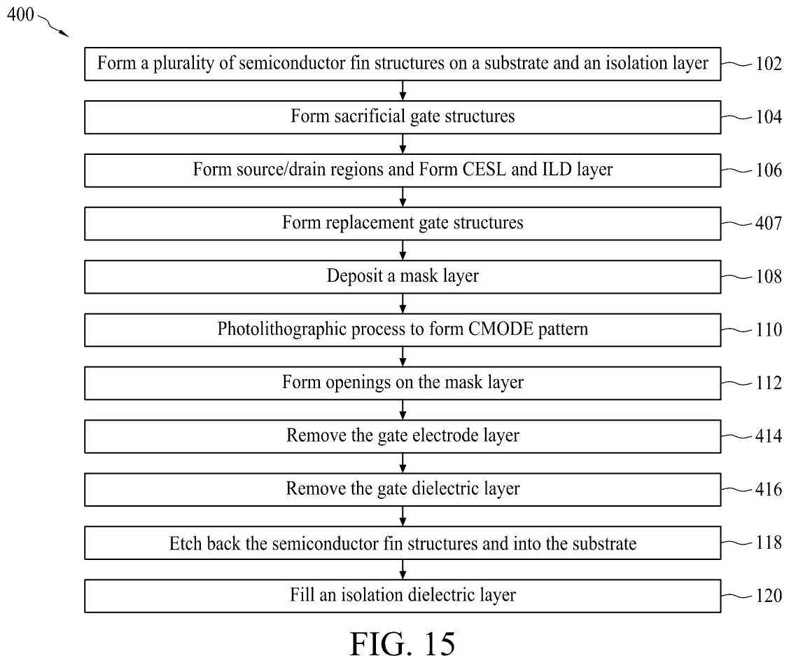

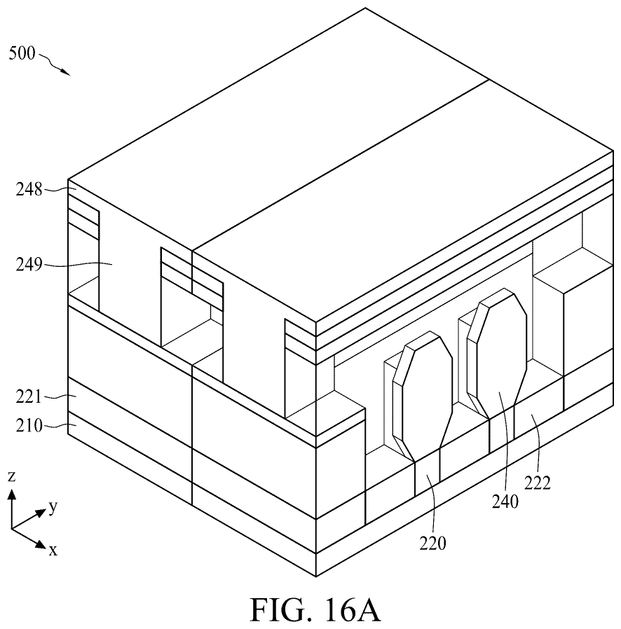

Embodiments of the present disclosure may also be used in form isolation structures in a CMODE process. FIG. 15 is a flow chart of a method 400 for manufacturing of a semiconductor substrate according to embodiments of the present disclosure. The method 400 relates to forming isolation structures using CMODE process. The method 400 is similar to the method 100 except that a replacement gate process is performed before the CMODE process.

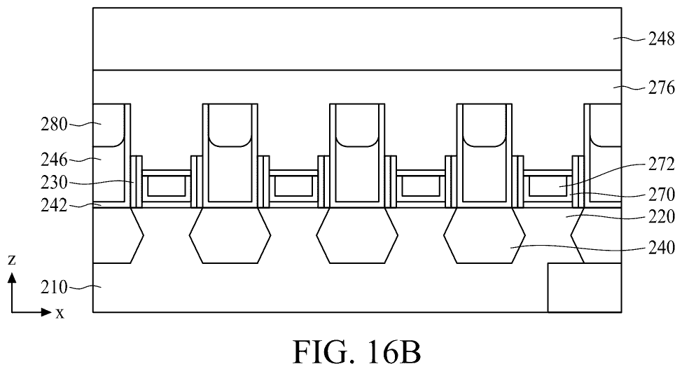

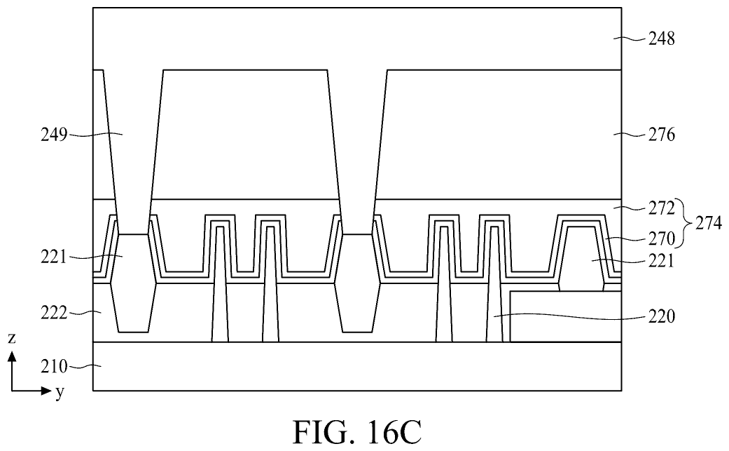

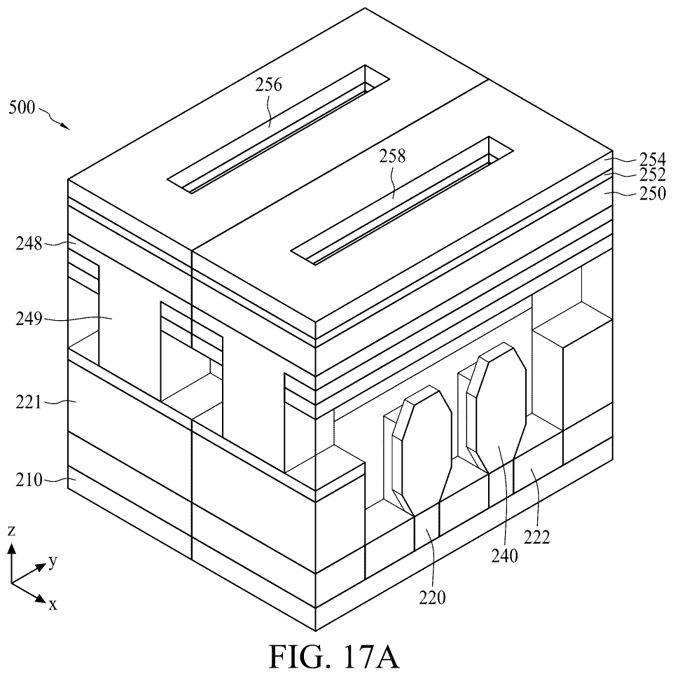

FIGS. 16A-16C, 17A-17C, 18A-18C, 19A-19C, 20A-20F, 21A-21C, and 22A-22C schematically illustrate various stages of manufacturing a semiconductor device 500 according to embodiments of the present disclosure.

FIGS. 16A-16C schematically demonstrate the semiconductor device 500 after operation 108 of the method 400. As shown in FIGS. 16A-16C, the semiconductor device 500 includes a plurality of semiconductor fins 220 formed over a semiconductor substrate 210. Gate structures 274 are formed over the semiconductor fins 220. The gate structures 274 includes a gate dielectric layer 270 and a gate electrode layer 272. Sidewall spacers 230 are formed on sidewalls of the gate structures 274. Epitaxial source/drain regions 240 are formed between sections of the semiconductor fins 220. An CESL 242 is formed over the epitaxial source/drain regions 240 and an ILD layer 246 is formed over the CESL 242. A cap layer 280 may be disposed over the ILD layer 246. In some embodiments, a self-aligned contact (SAC) layer 276 is disposed over the gate structures 274.

A mask layer 348 is deposited on the SAC layer 280. The mask layer 248 is used to form a CMODE pattern. In some embodiments, dielectric fins 221 may be formed between the semiconductor fins 220. In some embodiments, cut gate openings may be formed over the dielectric fins 221, and the mask layer 248 may be filled in the cut gate openings and in contact with the dielectric fins 221.

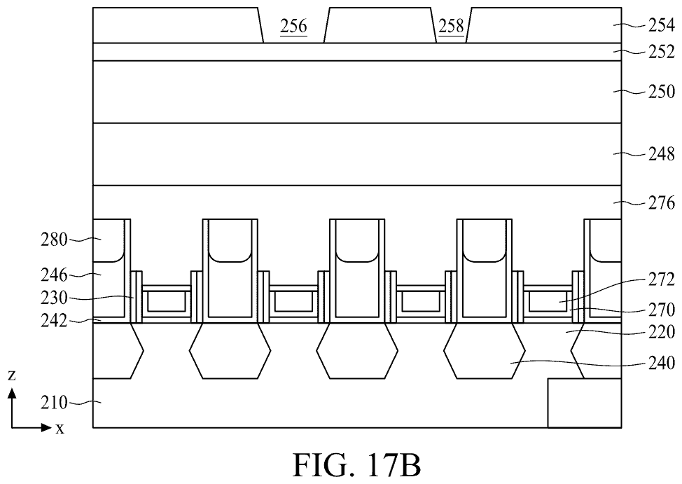

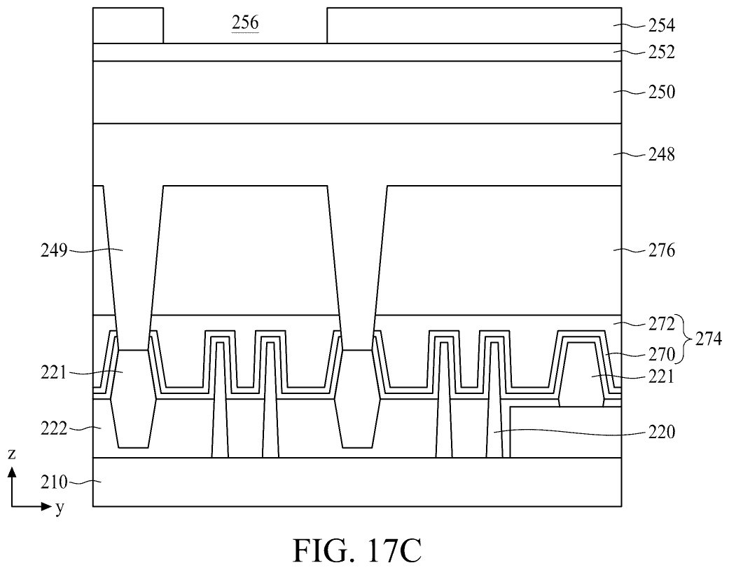

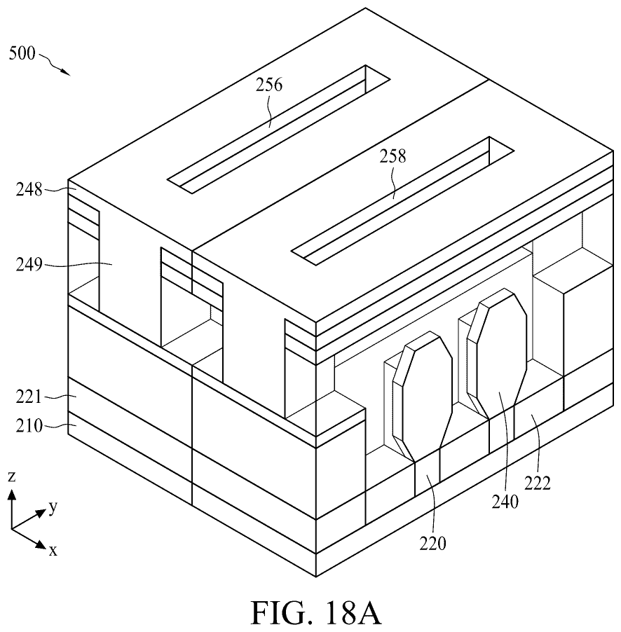

In operation 110, a photolithographic process is performed and a photoresist layer 254 is patterned with a CMODE pattern, as shown in FIGS. 17A-17C. In some embodiments, the CMODE pattern may be similar to any the patterns discussed in the semiconductor devices 10 and 10a-101. In some embodiments, the CMODE pattern may include wide openings 256 and narrow openings 258 aligned over the gate structures 274.

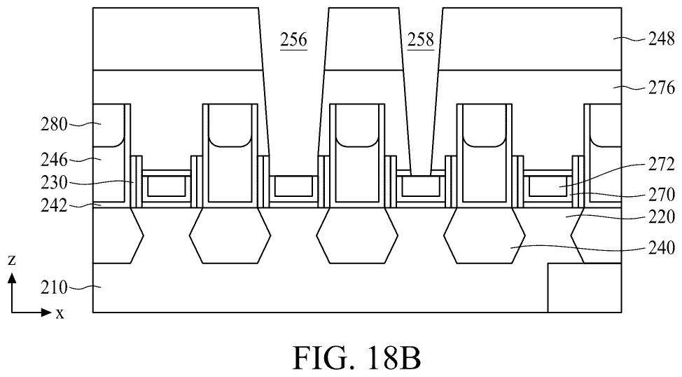

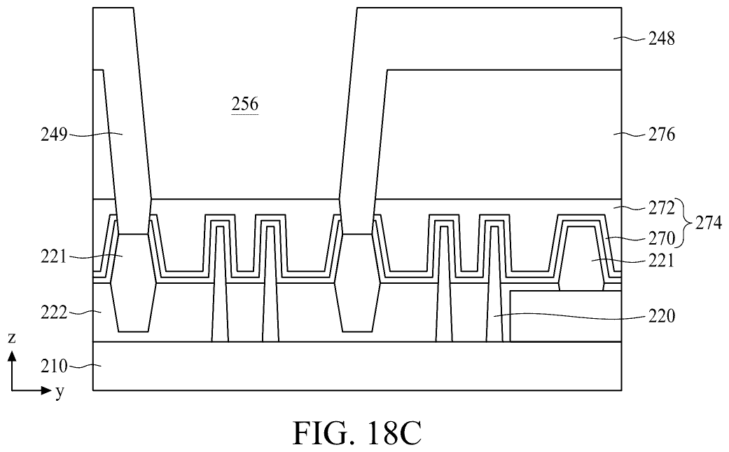

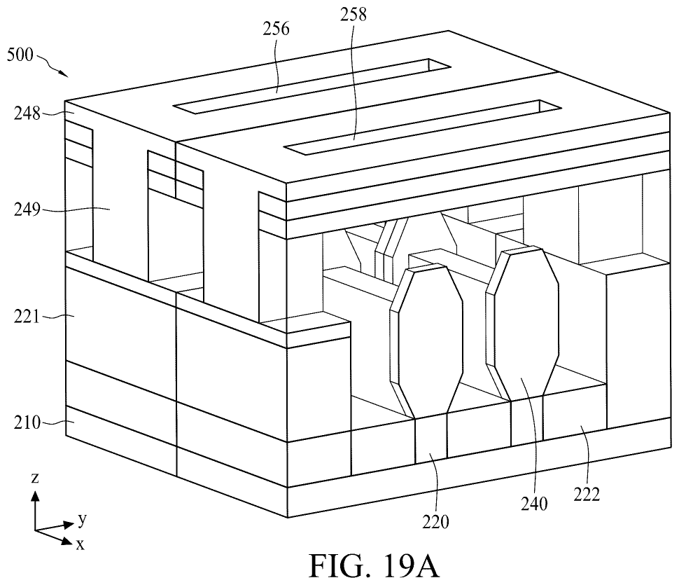

In operation 112, the openings 256 and 258 are transferred to the mask layer 248, as shown in FIGS. 18A-18C. In some embodiments, the SAC layer 276 may be removed during the pattern transfer process.

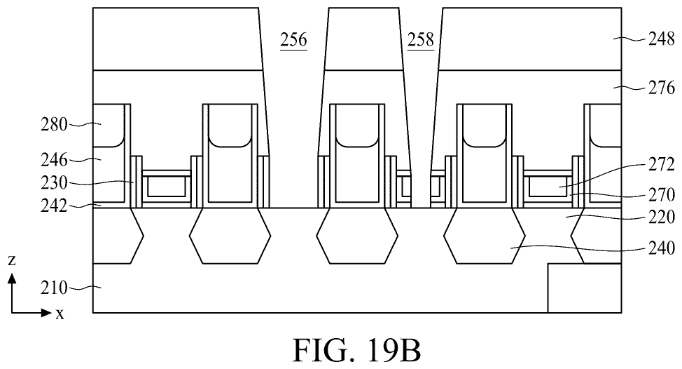

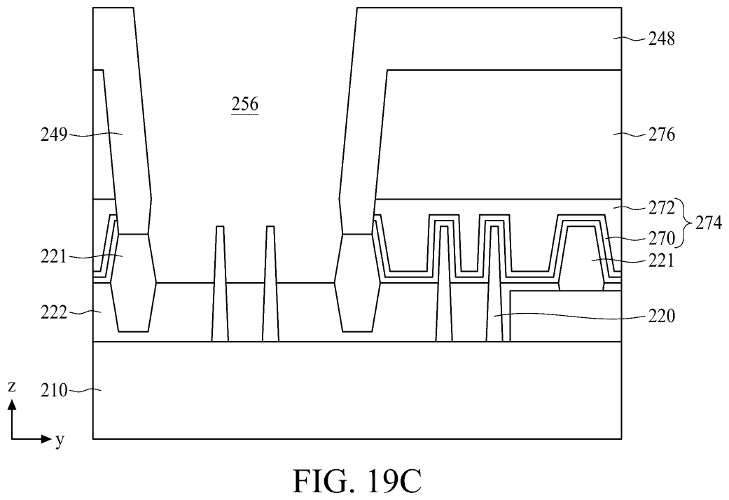

In operation 414, the gate electrode layer 272 is removed by suitable etch process to expose the gate dielectric layer 270. In operation 416, the gate dielectric layer 270 is removed by suitable etch process to expose the semiconductor fin 210 underneath, as shown in FIGS. 19A-19C.

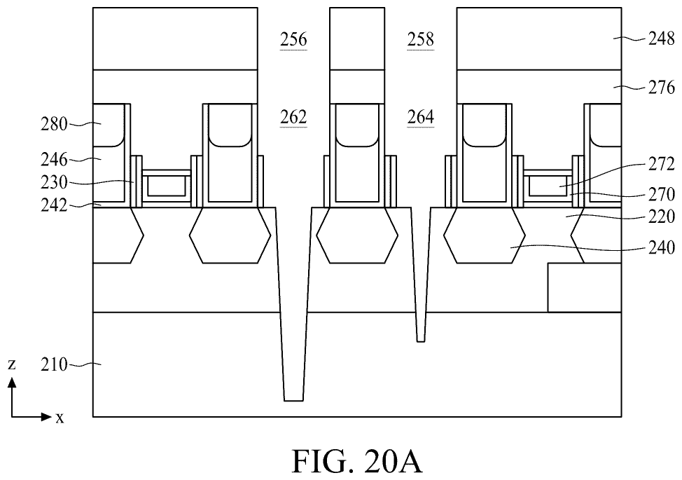

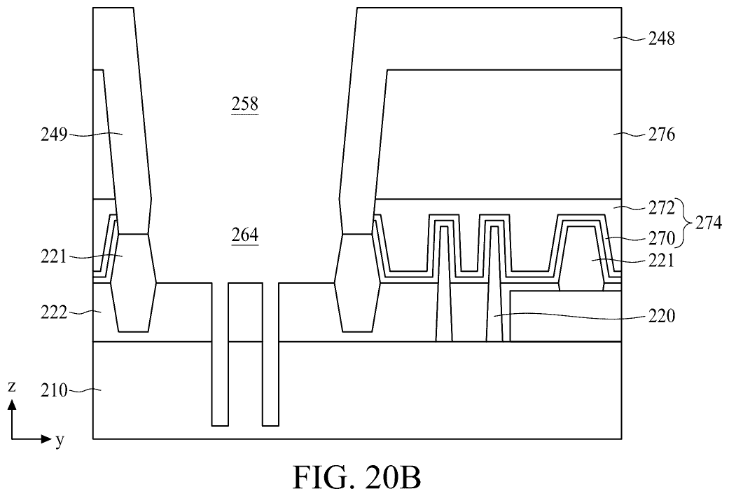

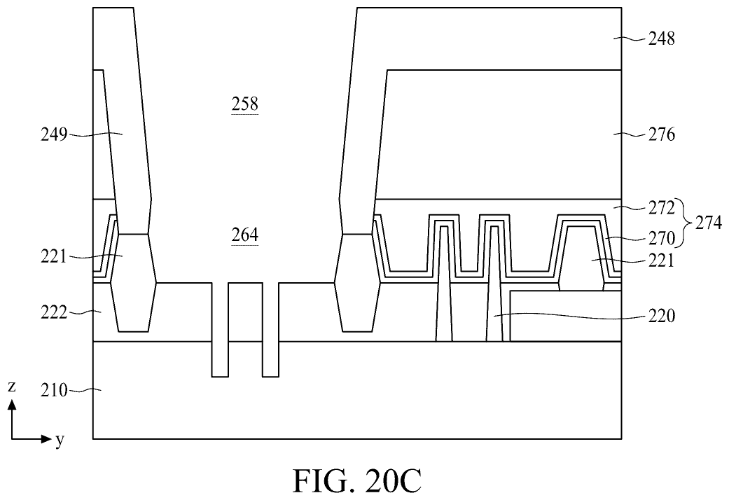

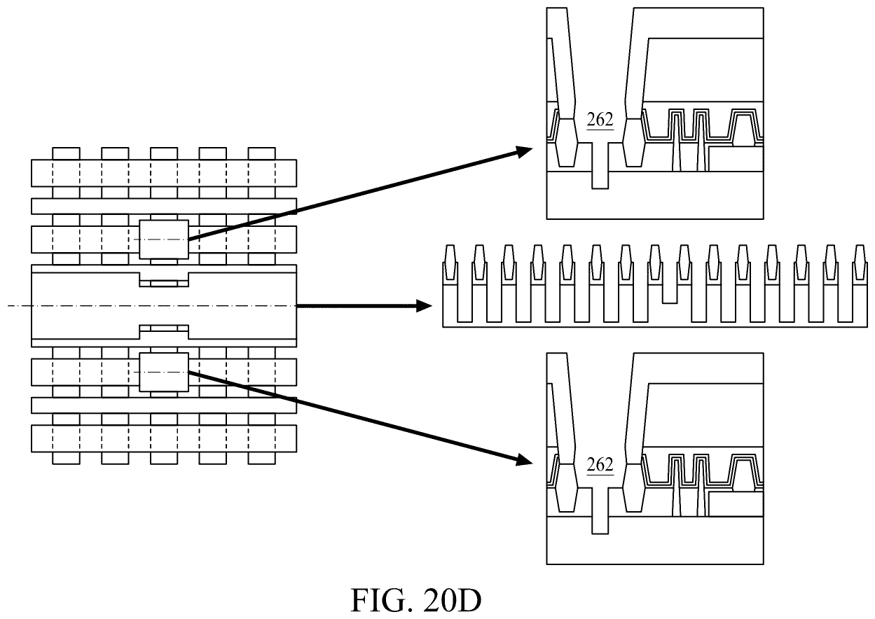

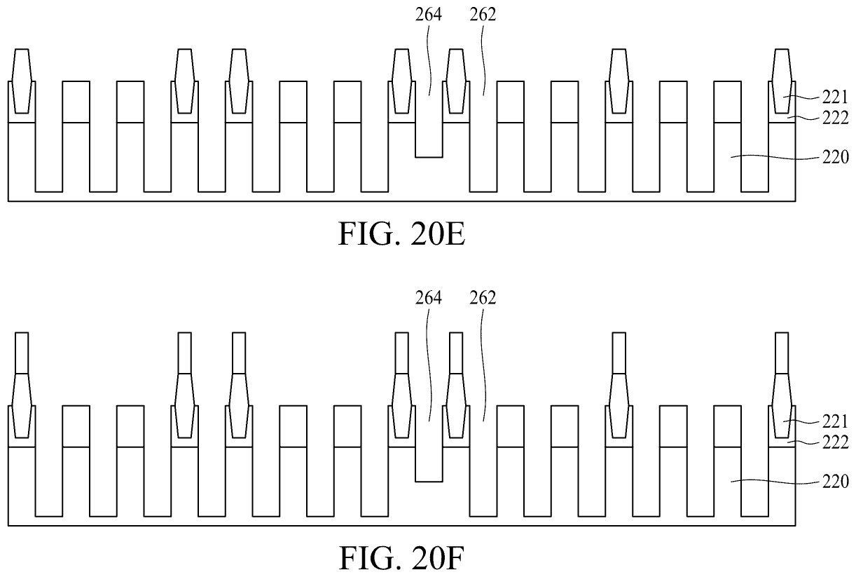

In operation 118, one or more etch processes may be performed to remove the exposed semiconductor fins 220 and the semiconductor substrate 210 and forming isolation openings 262 and 264. As shown in FIGS. 20A-20C, deeper isolation openings 262 may be formed through the wide openings 256 and shallower isolation openings 264 may be formed through the narrow openings 258.

Additionally, as shown in FIG. 20D, shallower isolation openings 264 may be formed from narrow segment of a mask openings with wide segments and narrow segments.

As shown in FIG. 20E, the dielectric fins 221 may be implanted in the isolation layer 222 according to the circuit design. As shown in FIG. 20F, the cut metal gate fill 249 may be formed over the dielectric fins 221. The cut metal gate fill 249 may be formed during deposition of the mask layer 248.

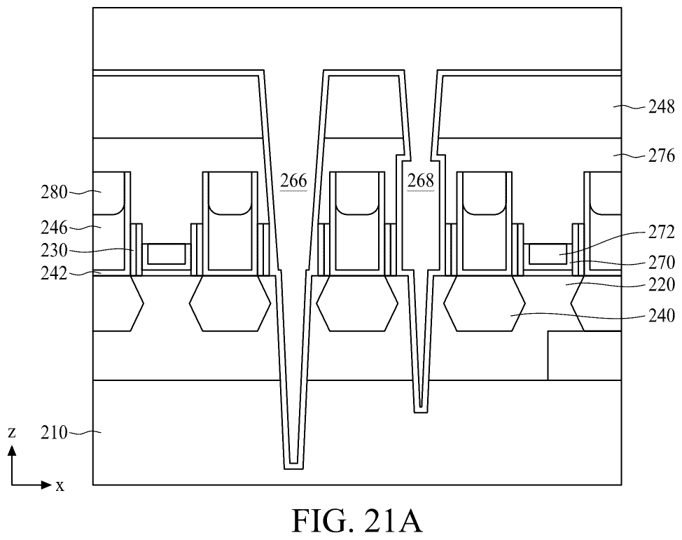

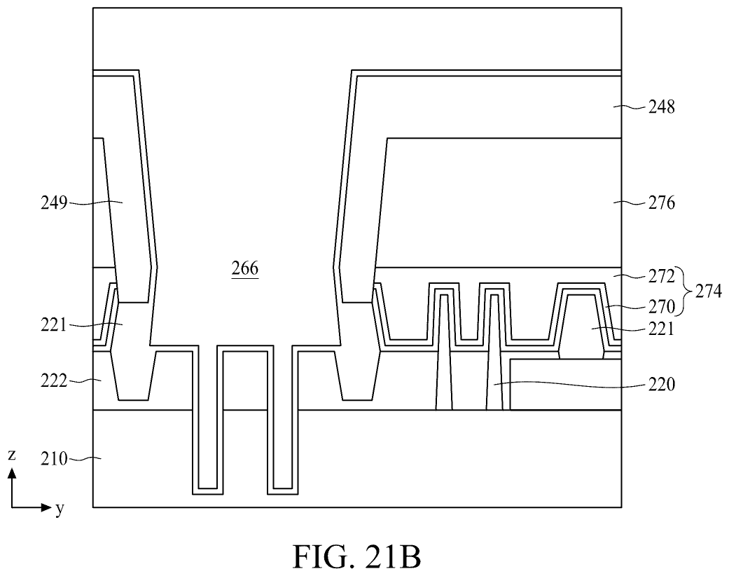

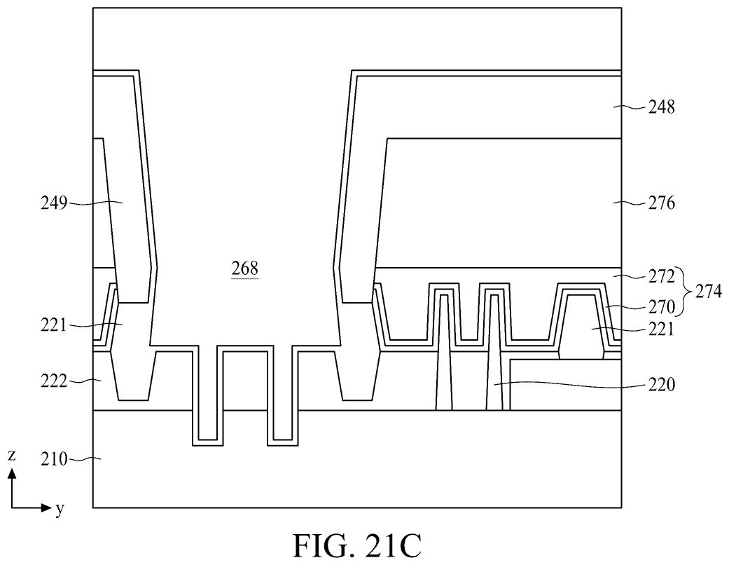

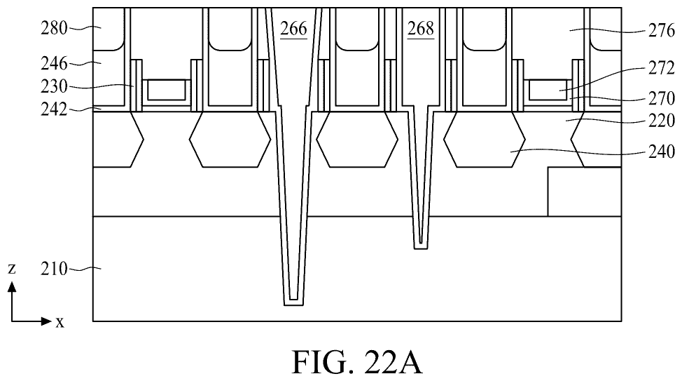

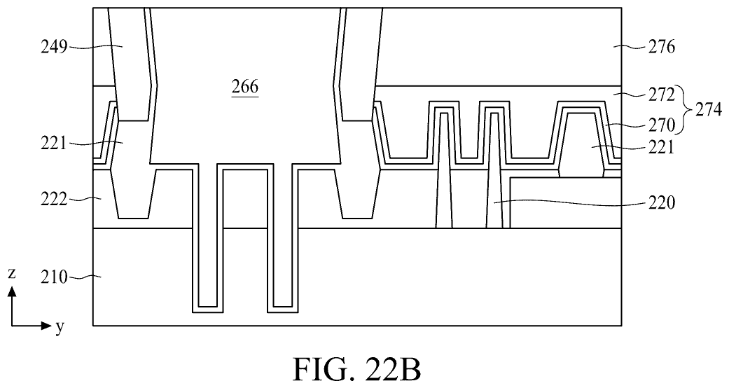

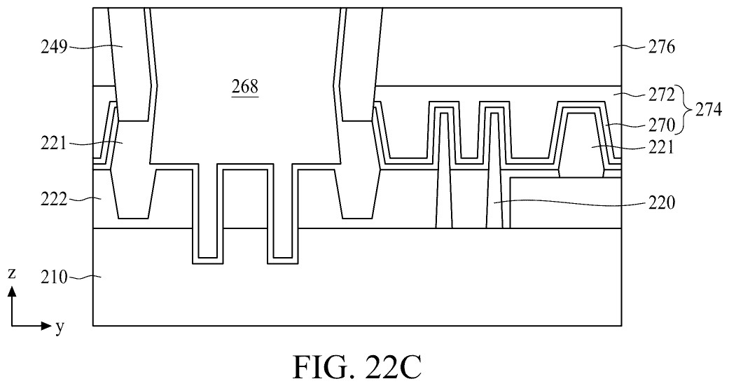

In operation 120, the openings 262 and 264 are filled with isolation material to form isolation structures 266, 268, as shown in FIGS. 21A-21C. A CMP process may be performed for further process, as shown in FIGS. 22A-22C.

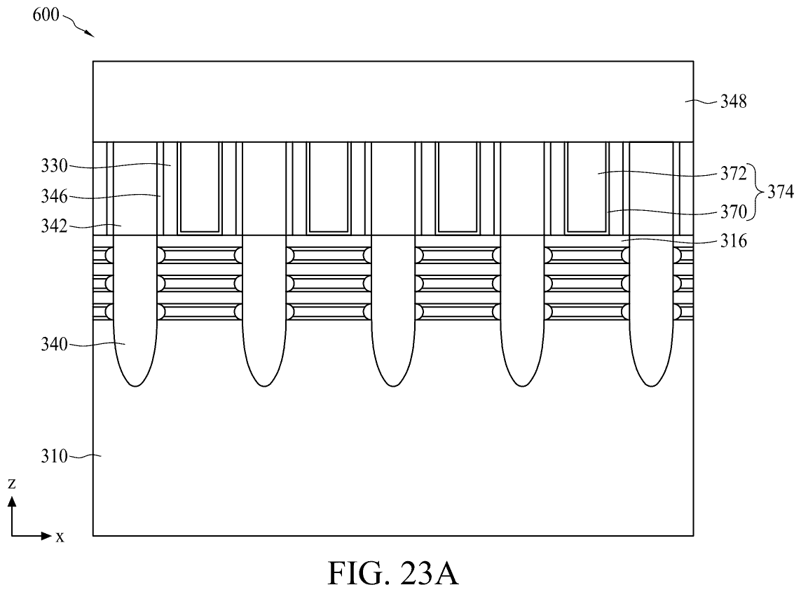

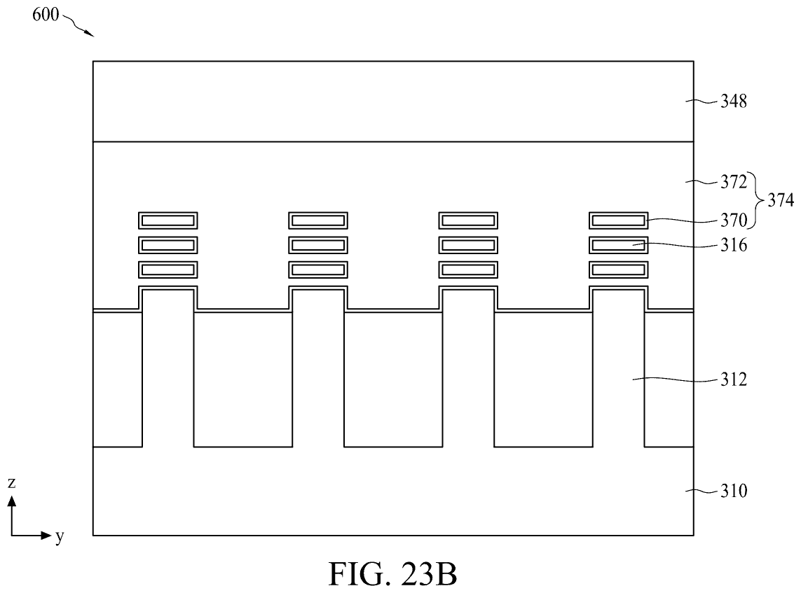

The semiconductor device 500 is a FinFET device. The method 400 may be used to fabricate a GAA device as well. FIGS. 23A-23B, 24A-24B, 25A-25B, and 26A-26B schematically illustrate various stages of manufacturing a semiconductor device according to embodiments of the present disclosure.

FIGS. 23A-23B schematically demonstrate the GAA device 600 after operation 108. The GAA device 600 includes a plurality of semiconductor fins 320 formed over a semiconductor substrate 310. Each of the semiconductor fins 320 includes a well portion 312 formed from the semiconductor substrate 310 and two or more semiconductor channel layers 316. Gate structures 374 are formed around the two or more semiconductor channel layers 316. The gate structures 374 includes a gate dielectric layer 370 and a gate electrode layer 372. Sidewall spacers 330 are formed on sidewalls of the gate structures 374. Epitaxial source/drain regions 340 are formed between the semiconductor channel layers 316. Inner spacers 332 are formed between the epitaxial source/drain regions 340 and the gate structures 374. An CESL 342 is formed over the epitaxial source/drain regions 340 and an ILD layer 346 is formed over the CESL 342. A mask layer 348 is deposited on the sacrificial gate structures 328 and the ILD layer 346. The mask layer 348 is used to form a CMODE pattern.

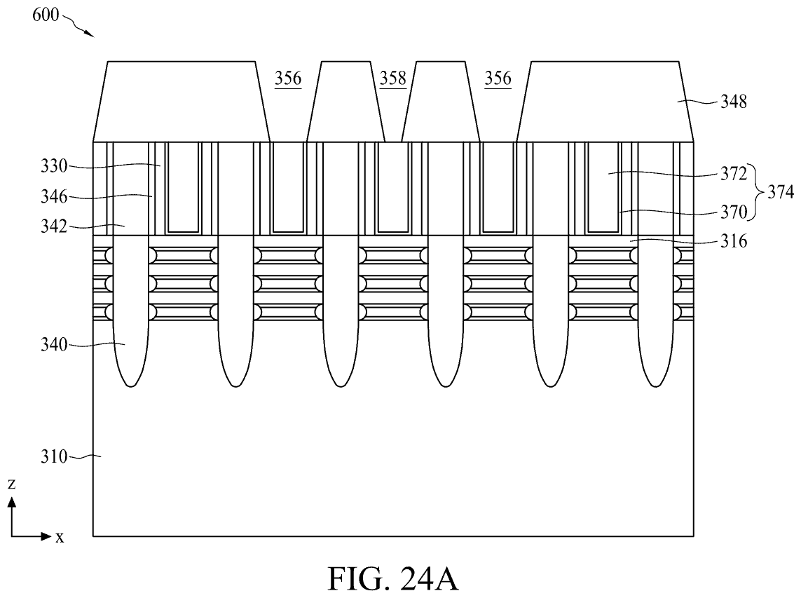

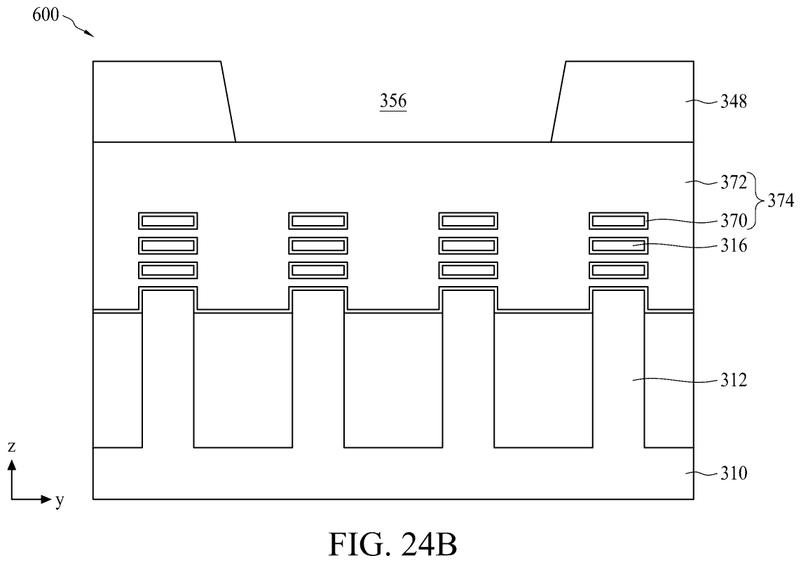

FIGS. 24A-24B schematically demonstrate the GAA device 600 after operation 112. A photolithographic process is performed and a photoresist layer and then transferred to the mask layer 348. In some embodiments, the CMODE pattern may be similar to any the patterns discussed in the semiconductor devices 10 and 10a-101. In some embodiments, the CMODE pattern may include wide openings 356 and narrow openings 358 aligned over the gate structures 374.

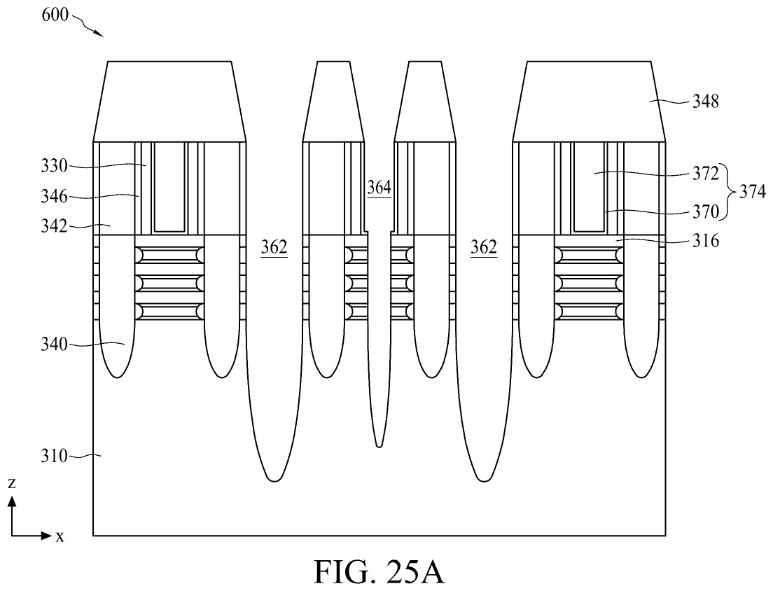

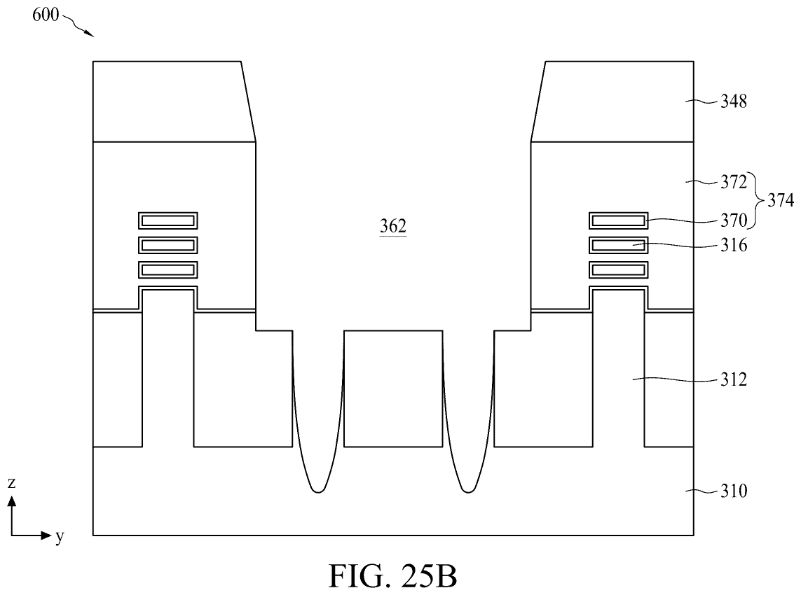

FIGS. 25A-25B schematically demonstrate the GAA device 600 after operation 118. Multiple etch processes may be performed to remove the gate electrode layer 372, the gate dielectric layer 370, and semiconductor channel layer 316, and the semiconductor substrate 310 and forming isolation openings 362 and 364. As shown in FIGS. 25A-25B, deeper isolation openings 362 may be formed through the wide openings 356 and shallower isolation openings 364 may be formed through the narrow openings 358.

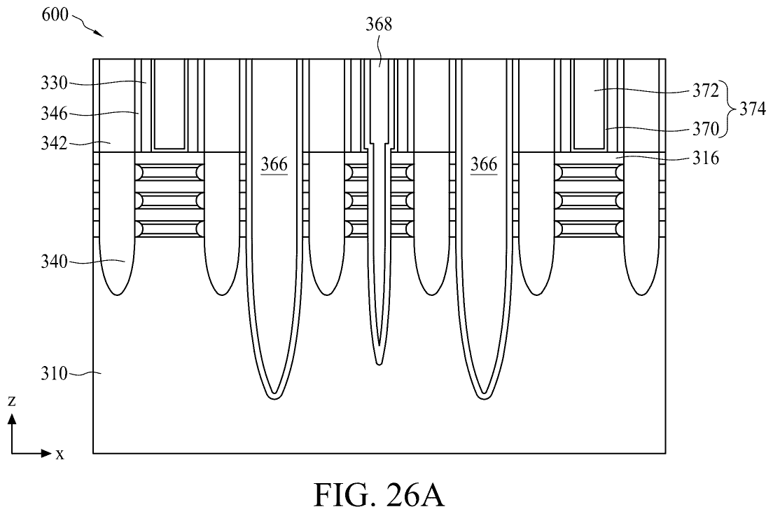

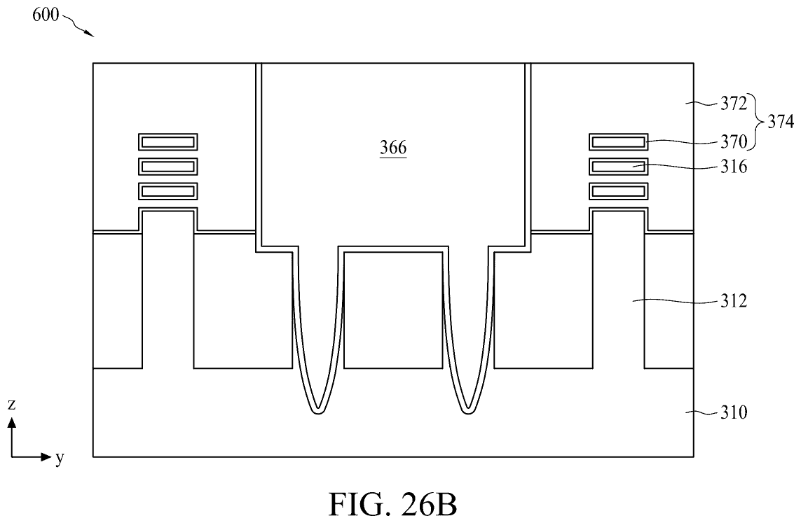

FIGS. 26A-26B schematically demonstrate the GAA device 600 after operation 122. Deep isolation structures 366 and shallow isolation structures 368 are formed in sections of the gate structures 374 and into the semiconductor substrate 310. The deep isolation structures 366 formed from a wide opening through the mask layer 348 provides electric isolation between the source/drain regions 340. The shallow isolation structures 368 provide pattern balance and prevent pattern loading during fabrication. In some embodiments, the gate structures 374 and the semiconductor channel layers 316 may be in contact with shallow isolation structures 368 in y-z plane.

Various embodiments or examples described herein offer multiple advantages over the state-of-art technology. The methods according to the present disclosure enables gate pitch scaling in CPODE or CMODE process without photoresist defects or performance loss.

It will be understood that not all advantages have been necessarily discussed herein, no particular advantage is required for all embodiments or examples, and other embodiments or examples may offer different advantages.

Some embodiments of the present provide a semiconductor device. The semiconductor device comprises a semiconductor substrate; a fin structure on the semiconductor substrate and extending along a first direction; a plurality of gate structures across the fin structure along a second direction; a plurality of source/drain regions over the fin structure and between the plurality of gate structures; a first isolation structure formed in a first gate structure of the plurality of gate structures, wherein the first isolation structure has a first width along the first direction; and a second isolation structure formed in a second gate structure of the plurality of the gate structures, wherein the second isolation structure has a second width along the first direction, the first gate structure is positioned immediately next to the second gate structure, and the first width is greater than the second width.

Some embodiments of the present provide a semiconductor device. The semiconductor device comprises a semiconductor substrate; a plurality of fin structures on the semiconductor substrate and extending along a first direction; a gate structure disposed across the plurality of fin structures and extending along a second direction; and an isolation structure disposed in the gate structure, wherein the isolation structure comprises: a first segment having a first width; and a second segment having a second width, wherein the first width is greater than the second width.

Some embodiments provide a method for forming a semiconductor device. The method comprises forming a plurality of fin structures on a substrate along a first direction; forming a plurality of gate structures across the plurality of fin structures; depositing a mask layer over the plurality of gate structures; forming a pattern in the mask layer, wherein the pattern comprises: a first opening in align with a first gate structure of the plurality of gate structures; and a second opening in align with the second gate structure of the plurality of gate structures, wherein the first gate structures and the second gate structure are immediately next to each other, the first opening has a first width along the first direction, the second opening has a second width along the first direction, and the first width is greater than the second width; forming a first isolation opening and a second isolation opening using the pattern in the mask layer; and depositing a dielectric layer to fill the first isolation opening and the second isolation opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a semiconductor substrate;
a fin structure on the semiconductor substrate and extending along a first direction;
a plurality of gate structures across the fin structure along a second direction;
a plurality of source/drain regions over the fin structure and between the plurality of gate structures;
a first isolation structure formed in a first gate structure of the plurality of gate structures, wherein the first isolation structure has a first width along the first direction; and
a second isolation structure formed in a second gate structure of the plurality of the gate structures, wherein the second isolation structure has a second width along the first direction, the first gate structure is positioned immediately next to the second gate structure, and the first width is greater than the second width.

2. The semiconductor device of claim 1, wherein the plurality of gate structures are evenly distributed along the first direction at a gate pitch.

3. The semiconductor device of claim 2, wherein the first width is greater than 0.5 times of the gate pitch.

4. The semiconductor device of claim 3, wherein the first isolation structure is a first distance away from the second isolation structure along the first direction, and the first distance is greater than 0.5 times of the gate pitch.

5. The semiconductor device of claim 1, wherein the first isolation structure cuts through the fin structure and extends into the semiconductor substrate for a first depth, the second isolation structure cuts through the fin structure and extends into the semiconductor substrate for a second depth, and the first depth is greater than the second depth.

6. The semiconductor device of claim 1, wherein the fin structure includes a single channel.

7. The semiconductor device of claim 1, wherein the fin structure includes two or more channels.

8. The semiconductor device of claim 1, further comprising a third isolation structure disposed in a third gate structure of the plurality of gate structures, wherein the third gate structure is disposed immediately next to the first gate structure, and the third isolation structure has a third width less than the first width.

9. The semiconductor device of claim 1, further comprising a third isolation structure disposed in a third gate structure of the plurality of gate structures, wherein the third gate structure is disposed immediately next to the second gate structure, and the third isolation structure has a third width greater than the second width.

10. A semiconductor device, comprising:
a semiconductor substrate;
a plurality of fin structures on the semiconductor substrate and extending along a first direction;
a gate structure disposed across the plurality of fin structures and extending along a second direction; and
an isolation structure disposed in the gate structure, wherein the isolation structure comprises:
a first segment having a first width; and
a second segment having a second width, wherein the first width is greater than the second width.

11. The semiconductor device of claim 10, wherein the first segment cuts into a first fin structure of the plurality of fin structures, and the second segment cuts into a second fin structure of the plurality of fin structures.

12. The semiconductor device of claim 11, wherein the first segment is connected to the second segment.

13. The semiconductor device of claim 12, wherein the first segment extends into the semiconductor substrate for a first depth, the second segment extends into the semiconductor substrate for a second depth, and the first depth is greater than the second depth.

14. The semiconductor device of claim 11, further comprising:
a second gate structure disposed next to the gate structure;
a second isolation structure disposed in the second gate structure, wherein the second isolation structure cuts into the second fin structure, the second isolation structure has a third width, and the third width is greater than the second width.

15. The semiconductor device of claim 14, wherein the first isolation structure further comprises:
a third segment cutting into a third fin structure of the plurality of fin structures, wherein the third segment and the first segment are connected to two ends of the second segment, the third segment has a fourth width, and the fourth width is greater than the second width.

16. A method comprising:
forming a plurality of fin structures on a substrate along a first direction;
forming a plurality of gate structures across the plurality of fin structures;
depositing a mask layer over the plurality of gate structures;
forming a pattern in the mask layer, wherein the pattern comprises:
a first opening in align with a first gate structure of the plurality of gate structures; and
a second opening in align with the second gate structure of the plurality of gate structures, wherein the first gate structures and the second gate structure are immediately next to each other, the first opening has a first width along the first direction, the second opening has a second width along the first direction, and the first width is greater than the second width;
forming a first isolation opening and a second isolation opening using the pattern in the mask layer; and
depositing a dielectric layer to fill the first isolation opening and the second isolation opening.

17. The method of claim 16, wherein forming the first isolation opening and the second isolation opening comprises:
etching the first and second gate structures to expose the fin structures;
etching through the fin structures and into the substrate, wherein the first isolation opening extends into the substrate for a first depth, the second isolation opening extends into the substrate for a second depth, and the first depth is greater than the second depth.

18. The method of claim 17, wherein forming the plurality of gate structures comprises forming a plurality of sacrificial gate structures, and further comprising:
after depositing the dielectric layer, performing a replacement process.

19. The method of claim 16, wherein the pattern further comprises:
a third opening in align with a third gate structure of the plurality of gate structures, wherein the first gate structures and the third gate structure are immediately next to each other, the third opening has a third width along the first direction, and the first width is greater than the third width.

20. The method of claim 16, wherein the second opening comprises:
a first segment;
a second segment connected to the first segment; and
a third segment connected to the second segment, wherein the first segment and the third segment are wider than the second segment.
